(19) United States
(12) Patent Application Publication
(10) Pub. No.: US 2026/0334180 A1
(43) Pub. Date: Oct. 22, 2026

(54) METHODS FOR FORMING SELF-ALIGNED FEATURES

(71) Applicants: Tokyo Electron Limited, Tokyo (JP); Geminatio, Inc., Schenectady, NY (US)

(72) Inventors: Anton deVilliers, Albany, NY (US); Jordan B. Greenough, Schenectady, NY (US); Max J. Klemes, Schenectady, NY (US); Daniel Fulford, Albany, NY (US); May Callahan, Schenectady, NY (US)

(21) Appl. No.: 19/537,049

(22) Filed: Feb. 11, 2026

Related U.S. Application Data
(60) Provisional application No. 63/792,139, filed on Apr. 21, 2025.

(51) Int. Cl. H10W 20/00; H10W 90/00

(52) U.S. Cl. CPC H10W 20/023; H10W 20/056; H10W 90/724

(57) ABSTRACT

A method includes providing a substrate including a through-silicon via (TSV) extending into the substrate from a first surface of the substrate, recessing the TSV to form a first recess in the substrate, and filling the first recess with a first polymer material. The first polymer material includes an agent-generating ingredient. A first surface of the first polymer material is level with the first surface of the substrate. The method further includes forming a first overcoat layer over the first surface of the first polymer material and the first surface of the substrate, generating a solubility-shifting agent in the first polymer material from the agent-generating ingredient, diffusing the solubility-shifting agent into the first overcoat layer to form a first deprotected region in the first overcoat layer, and removing the first deprotected region of the first overcoat layer and the first polymer material to form a second recess.

### CROSS-REFERENCE TO RELATED APPLICATIONS

This application claims the benefit of U.S. Provisional Application No. 63/792,139, filed on Apr. 21, 2025, which application is hereby incorporated herein by reference.

### TECHNICAL FIELD

The present disclosure relates generally to methods of processing a substrate, and, in particular embodiments, to methods for forming self-aligned features.

### BACKGROUND

Semiconductor devices are fabricated through sequential deposition and patterning of various materials on a substrate to form integrated electronic components and interconnect elements. As technology advances, feature sizes continue to shrink to increase component density, needing increasingly improved alignment between successive layers. Even minor misalignments can lead to increased resistance, open circuits, or electrical shorts.

Photolithography serves as a patterning method in semiconductor fabrication, involving coating a substrate with photoresist, exposing it to patterned radiation, and developing it to form a relief pattern that can be transferred to underlying layers. Traditional alignment methods rely on optical registration marks and sophisticated alignment systems, but as dimensions shrink to nanometer scales, these approaches face fundamental limitations in achieving the desired alignment.

Self-alignment techniques have emerged as an alternative approach to address these challenges by leveraging the physical or chemical properties of existing structures to define the position of subsequent features. These techniques reduce dependence on precise lithographic alignment, making them less susceptible to process variations and tool limitations.

### SUMMARY

In accordance with an embodiment, a method includes providing a substrate including a through-silicon via (TSV), where the TSV extends into the substrate from a first surface of the substrate; recessing the TSV to form a first recess in the substrate; filling the first recess with a first polymer material, the first polymer material including a first agent-generating ingredient, a first surface of the first polymer material being level with the first surface of the substrate; forming a first overcoat layer over the first surface of the first polymer material and the first surface of the substrate; generating a first solubility-shifting agent in the first polymer material from the first agent-generating ingredient; diffusing the first solubility-shifting agent into the first overcoat layer to form a first deprotected region in the first overcoat layer; and removing the first deprotected region of the first overcoat layer and the first polymer material to form a second recess.

In accordance with another embodiment, a method includes providing a substrate including a through-silicon via (TSV), where the TSV extends into the substrate from a first surface of the substrate; etching back the TSV to form a first recess in the substrate; depositing a first polymer material in the first recess, the first polymer material including a first agent-generating ingredient; forming an overcoat layer over the first polymer material and the substrate; generating a first solubility-shifting agent in the first polymer material from the first agent-generating ingredient; diffusing the first solubility-shifting agent into the overcoat layer to form a deprotected region in the overcoat layer; removing the deprotected region of the overcoat layer to form a second recess in the overcoat layer; removing the first polymer material to extend the second recess into the substrate; performing a freeze process on the overcoat layer to form a protective layer on exposed surfaces of the overcoat layer; overfilling the second recess with a second polymer material, the second polymer material including a second agent-generating ingredient; and patterning the second polymer material to form a third recess in the second polymer material and expose the second recess.

In accordance with yet another embodiment, a method includes providing a substrate including a through-silicon via (TSV), where the TSV extends into the substrate from a first surface of the substrate; etching the TSV to form a first recess in the substrate; filling the first recess with a first photoresist, a first surface of the first photoresist being level with the first surface of the substrate; forming an overcoat layer over the first surface of the first photoresist and the first surface of the substrate; generating a first solubility-shifting agent in the first photoresist; diffusing the first solubility-shifting agent into the overcoat layer to form a deprotected region in the overcoat layer; dissolving the deprotected region of the overcoat layer and the first photoresist to form a second recess; performing a freeze process on the overcoat layer; depositing a second photoresist in the second recess and over the overcoat layer; and patterning the second photoresist to form a third recess in the second photoresist and expose the second recess.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1N illustrate cross-sectional views of intermediate stages in the manufacturing of a semiconductor structure, in accordance with various embodiments;

FIGS. 1O-1Q illustrate cross-sectional views of intermediate stages in planarizing a polymer material, in accordance with various embodiments;

FIGS. 1R and 1S illustrate cross-sectional views of intermediate stages in planarizing a polymer material, in accordance with various embodiments;

FIGS. 2A-2C illustrate cross-sectional views of intermediate stages in the manufacturing of a semiconductor structure, in accordance with various embodiments;

FIGS. 3A-3D illustrate cross-sectional views of intermediate stages in the manufacturing of a semiconductor structure, in accordance with various embodiments;

FIGS. 4A-4H illustrate cross-sectional views of intermediate stages in the manufacturing of a semiconductor structure, in accordance with various embodiments;

FIGS. 5A-5E illustrate cross-sectional views of intermediate stages in the manufacturing of a semiconductor structure, in accordance with various embodiments;

FIGS. 6A and 6B illustrate a flow diagram of a method for forming self-aligned features, in accordance with various embodiments;

FIG. 7 illustrates a flow diagram of a method for forming self-aligned features, in accordance with various embodiments;

FIGS. 8A and 8B illustrate a flow diagram of a method for forming self-aligned features, in accordance with various embodiments;

FIG. 9 illustrates a flow diagram of a method for planarizing a polymer layer, in accordance with various embodiments; and

FIG. 10 illustrates a flow diagram of a method for planarizing a polymer layer, in accordance with various embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

While various embodiments of the present disclosure are described primarily in the context of backside power distribution networks and through-substrate via (TSV) connections for semiconductor wafers, it should also be appreciated that these embodiments may also apply to other interconnect applications benefiting from self-aligned contact formation. In particular, various embodiments of the present disclosure may similarly apply to wafer-level packaging, die-to-die bonding applications, interposer technologies, and other three-dimensional integrated circuit architectures where improved alignment between vertical conductive structures and overlying metallization layers is required.

Embodiments of the present disclosure provide methods for forming backside connections on semiconductor wafers using self-aligned technology. The methods address challenges in connecting vertical conductive structures, such as through-substrate vias (TSVs), with overlying metallization layers while achieving improved alignment tolerances. Various embodiments utilize acid-containing polymer plugs positioned within recessed contact areas to create localized chemical changes in overcoat materials, enabling selective removal of specific regions without affecting the entire overcoat layer.

In various embodiments, the process begins with a substrate having TSVs extending from a backside surface to devices on a front side surface. The TSVs are filled with conductive material and subsequently recessed below the backside surface to form recesses. These recesses are filled with a polymer material comprising a solubility-shifting agent generating ingredient, such as a thermal acid generator (TAG) or photoacid generator (PAG). An overcoat layer is deposited over the polymer material and substrate surface.

A solubility-shifting agent (e.g., acid) can be generated from the solubility-shifting agent generating ingredient through various methods including thermal processing or electromagnetic radiation exposure. Upon generation, the solubility-shifting agent diffuses from the polymer plugs into regions of the overcoat layer, causing these regions to undergo solubility changes relative to a predetermined developer. This diffusion process creates deprotected regions that are self-aligned to the underlying vertical conductive structures, reducing or eliminating overlay tolerance issues associated with conventional lithographic alignment techniques.

In some embodiments, the deprotected regions of the overcoat layer and polymer plugs are removed to form openings that extend into the substrate. A freeze process may be performed on the remaining overcoat layer to form a protective layer on exposed surfaces, preventing unwanted dissolution during subsequent processing steps. Additional polymer layers can be deposited and patterned to create relief patterns for dual damascene structures. The patterning of upper polymer layers can utilize conventional lithographic techniques with relaxed alignment tolerances since the desired alignment has already been achieved through the self-aligned chemical process.

Embodiments of the present disclosure enable the formation of conductive features within the self-aligned openings and relief patterns, creating electrical connections between the TSVs and backside power distribution networks or other interconnect structures. The method provides advantages over conventional approaches by coupling very small dimensionality features with large dimensionality features while maintaining improved alignment. These and additional details are further discussed below.

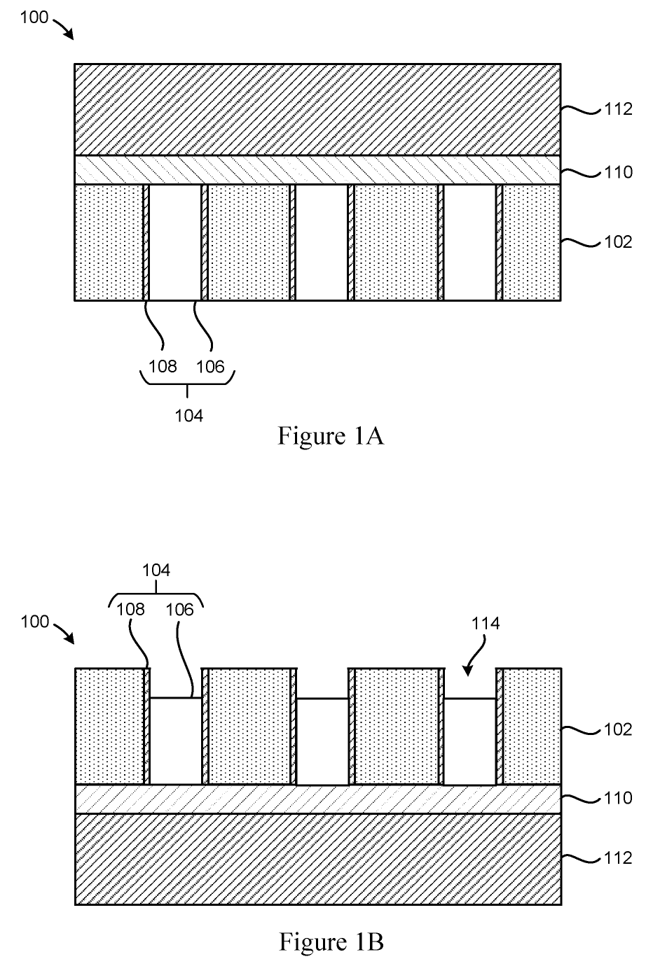

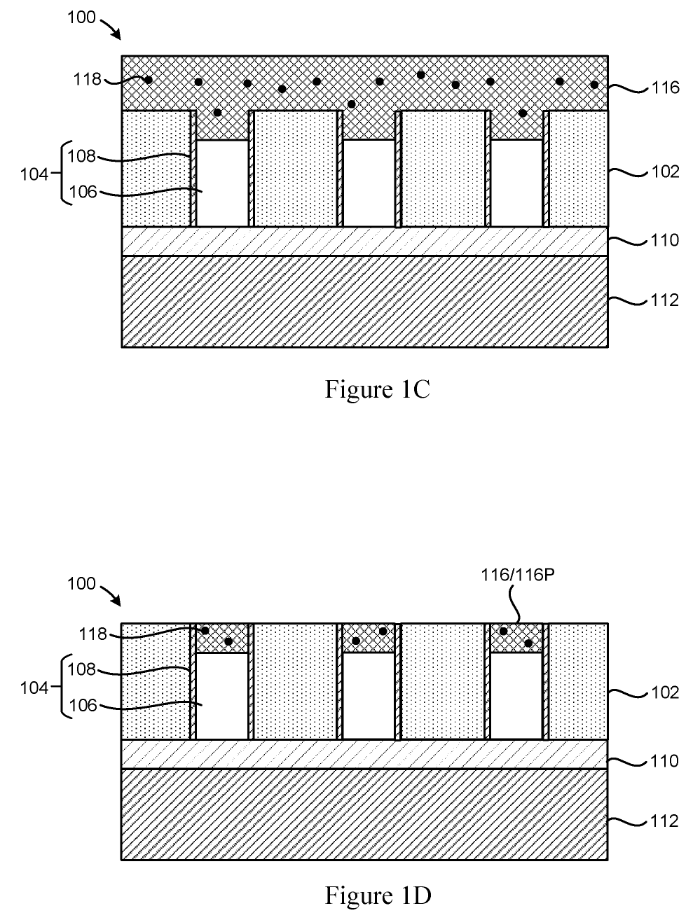

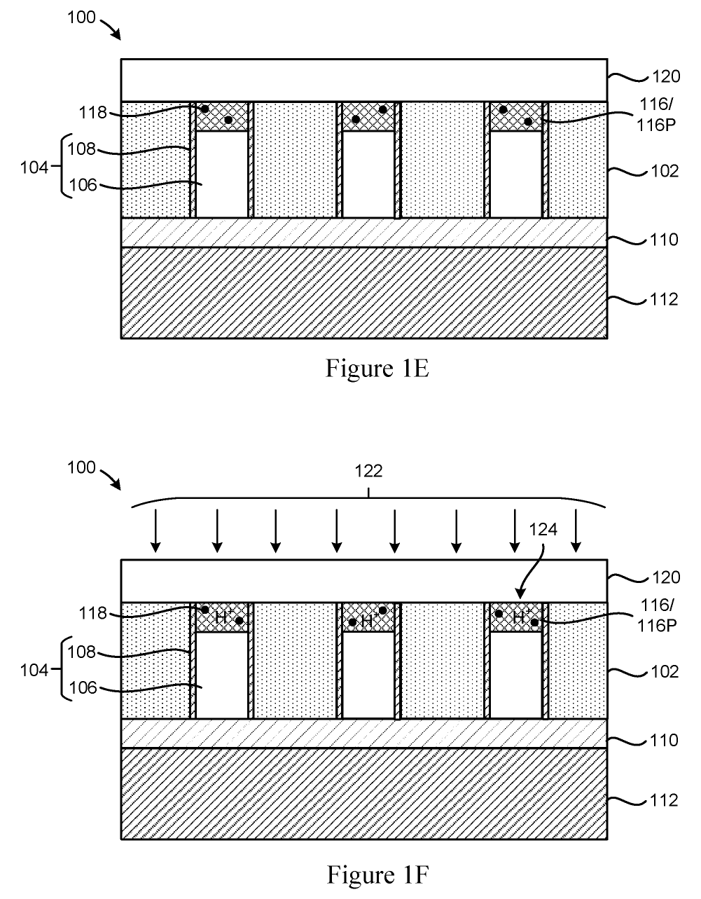

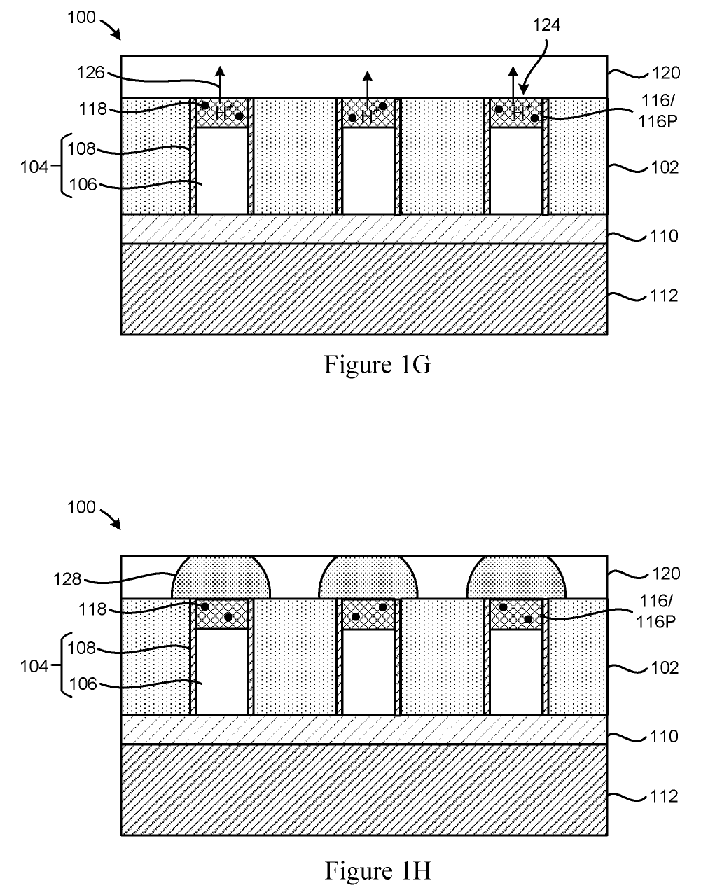

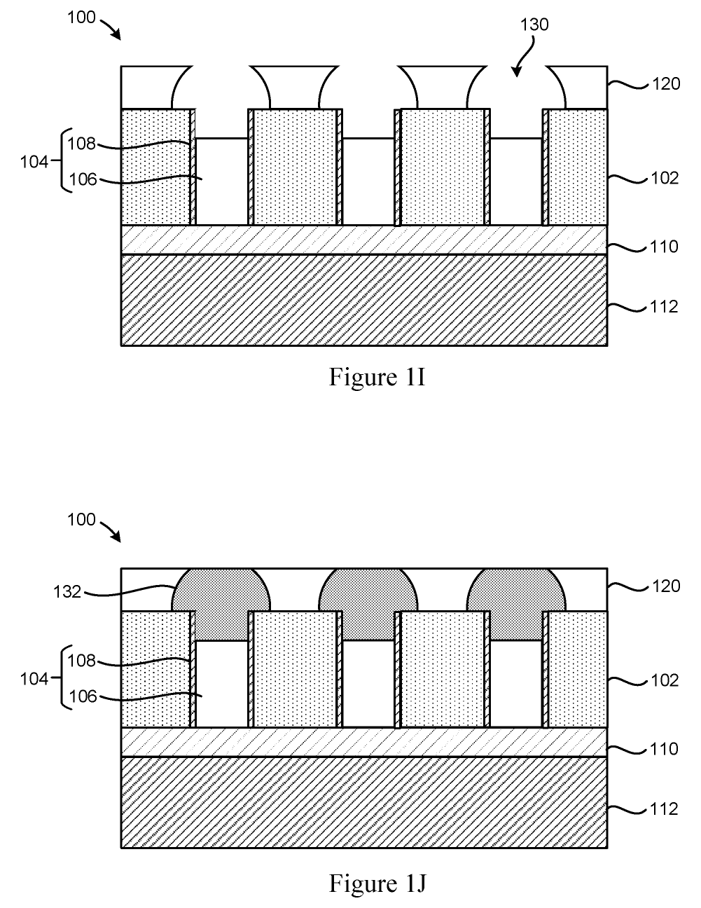

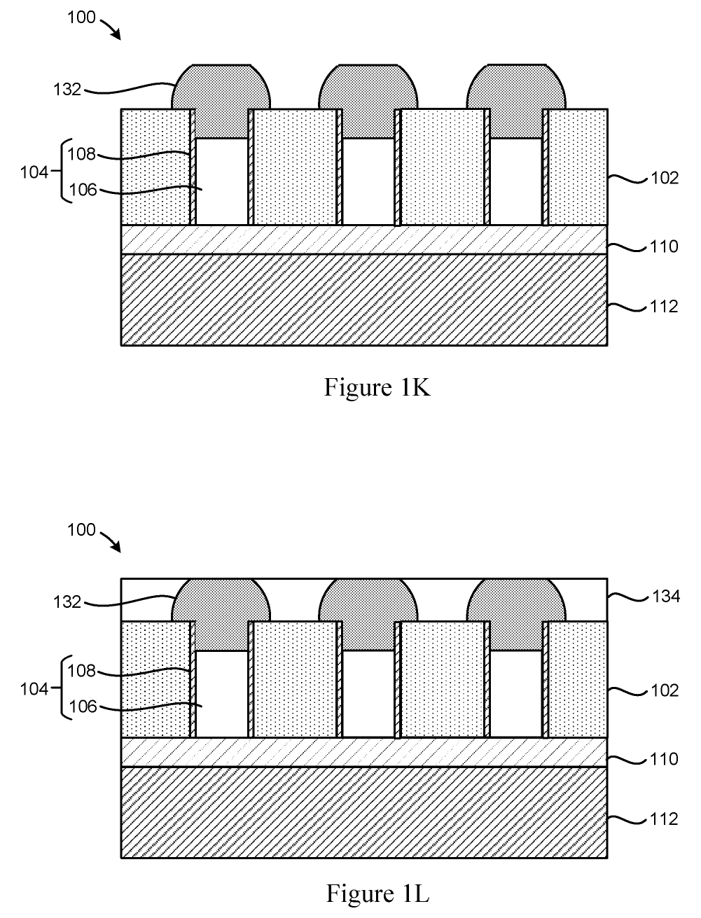

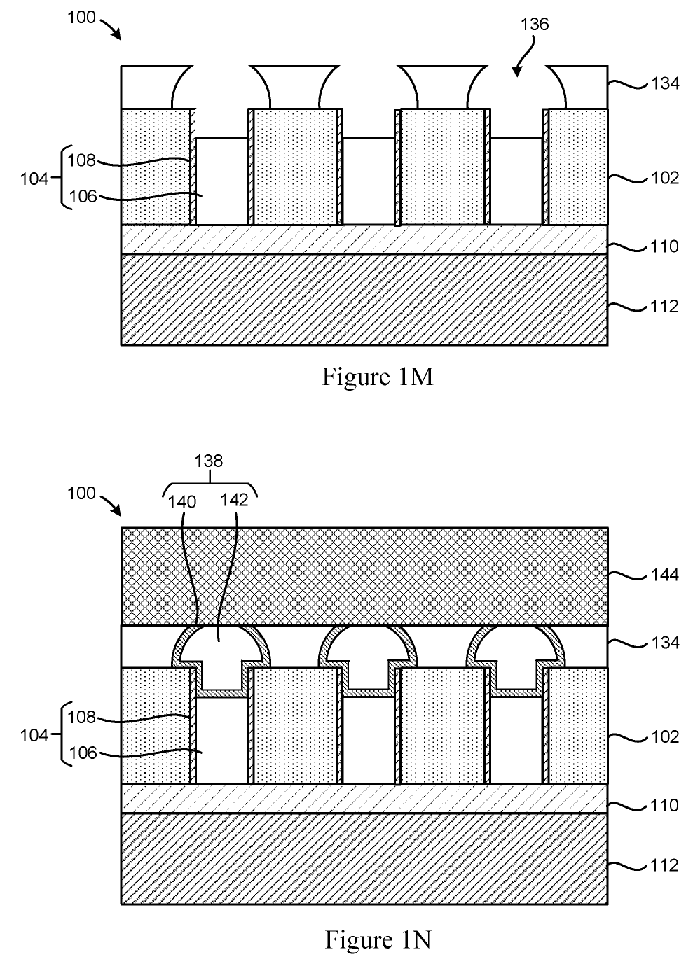

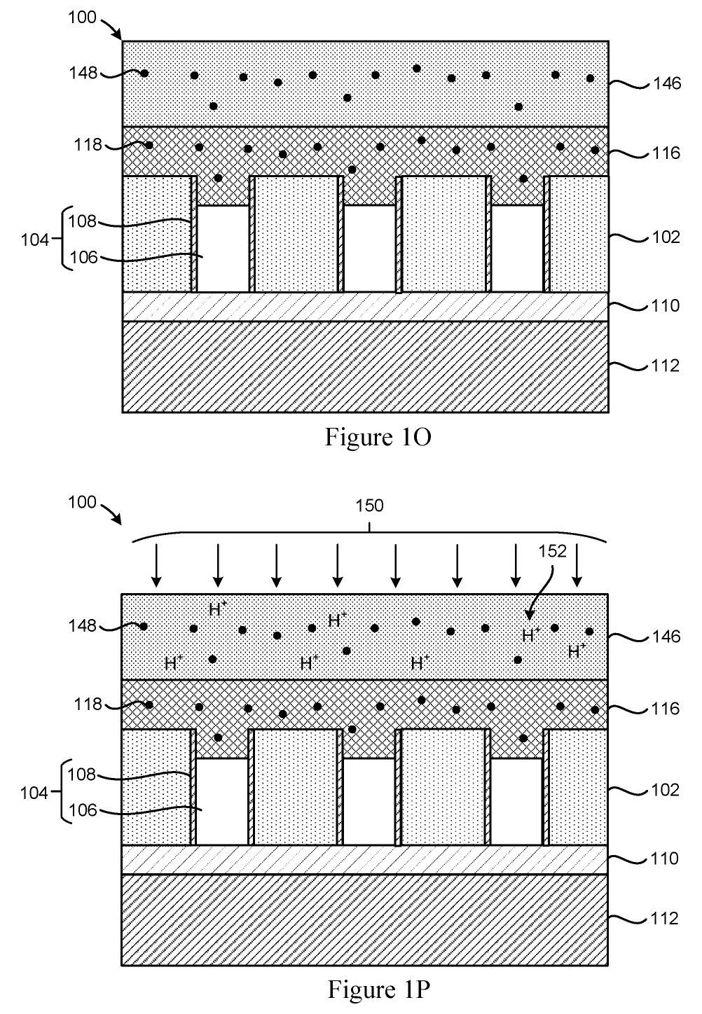

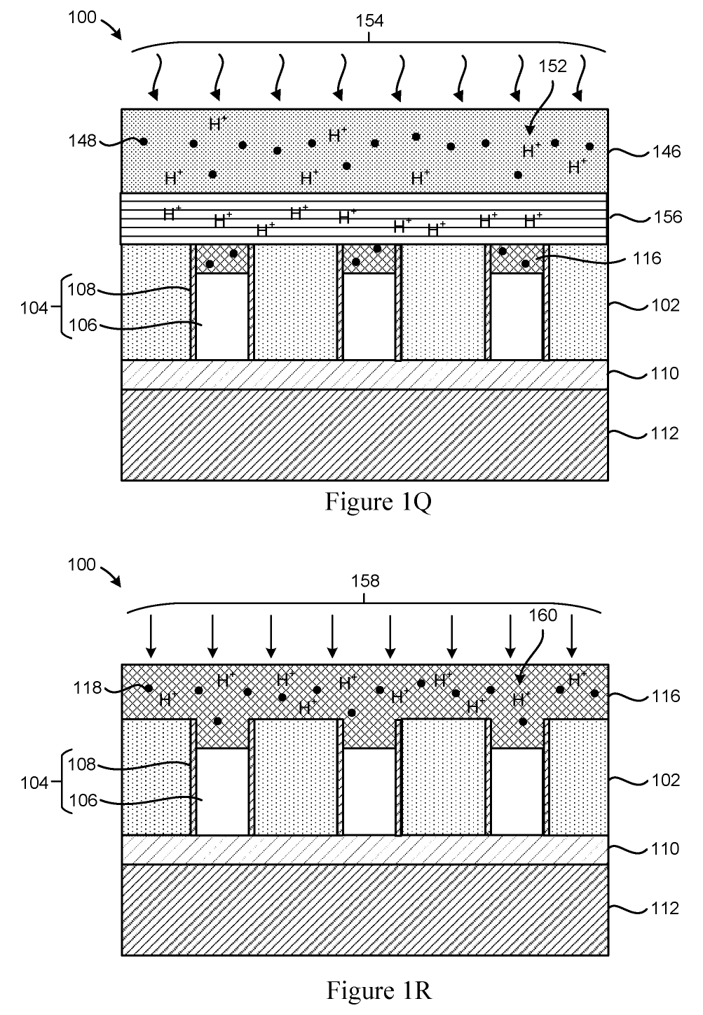

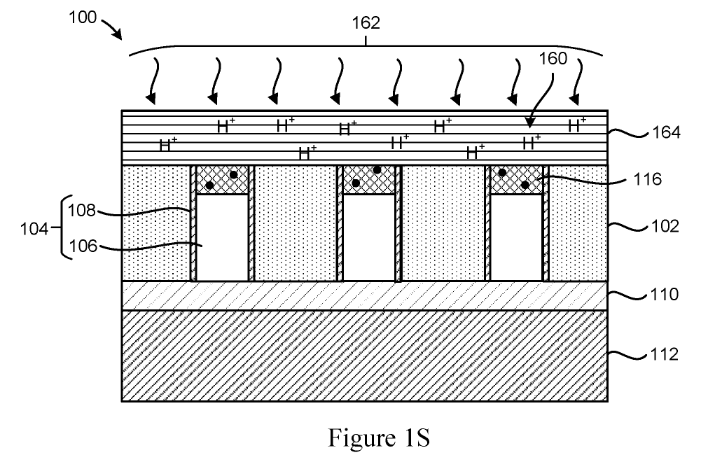

FIGS. 1A-1N illustrate cross-sectional views of intermediate stages in the manufacturing of a semiconductor structure 100, in accordance with various embodiments. The semiconductor structure 100 comprises a substrate 102 that serves as a foundation for the structure. In some embodiments, the substrate 102 may include a semiconductor material such as silicon, silicon germanium, silicon carbide, gallium arsenide, or other suitable semiconductor materials. In other embodiments, substrate 102 may comprise heterogeneous layers such as silicon germanium on silicon, gallium nitride on silicon, silicon carbon on silicon, or layers of silicon on a silicon or silicon-on-insulator (SOI) substrate.

Extending through the substrate 102 are TSVs 104 that provide vertical electrical connectivity. In some embodiments, each of the TSVs 104 comprises a conductive material 106 and a liner 108 extending along sidewalls of the conductive material 106. In one or more embodiments, the conductive material 106 may comprise copper, tungsten, aluminum, ruthenium, cobalt, molybdenum, combinations thereof, alloys thereof, or the like. In one or more embodiments, the liner 108 may comprise an insulating material such as silicon oxide, silicon nitride, silicon oxynitride, a combination thereof, or the like. The TSVs 104 may be formed using suitable via formation techniques including etching, deposition, and planarization processes.

Formed on a front side of the substrate 102 is a device layer 110 that comprises active and/or passive semiconductor devices and circuit elements. The device layer 110 may comprise various semiconductor devices including transistors, capacitors, resistors, diodes, and other circuit components formed using suitable semiconductor fabrication processes. The device layer 110 represents the functional circuitry that will be electrically connected through the backside connections formed in subsequent processing steps.

An interconnect structure 112 is formed over the device layer 110 and provides electrical routing between various circuit elements. The interconnect structure 112 may comprise multiple metallization levels separated by dielectric layers, forming a network of electrical connections. In various embodiments, interconnect structure 112 may include copper damascene wiring, aluminum interconnects, or other metallization schemes used in integrated circuit fabrication.

In FIG. 1B, the conductive materials 106 within the TSVs 104 are recessed below the backside surface of the substrate 102 to form recesses 114, while the liners 108 remain along sidewalls of the recesses 114. In various embodiments, the recessing process may be accomplished through etch-back techniques that selectively remove portions of the conductive materials 106 while leaving the surrounding substrate 102 and liners 108 substantially intact. The etch-back process may utilize wet etching, dry etching, or plasma etching techniques depending on the specific conductive material 106 being processed.

In other embodiments, the recesses 114 may be formed through chemical mechanical planarization processes rather than etch-back techniques. Chemical mechanical planarization (CMP) can create dish-shaped recesses in the conductive material 106. In embodiments utilizing CMP, the process conditions may be adjusted to create an over-polish condition that results in the desired recess depth.

The depth of the recesses 114 is controlled to provide sufficient volume for accommodating solubility-shifting agents in subsequent processing steps. In various embodiments, the depth of the recesses 114 may range from 20 nanometers to 2000 nanometers, depending on the specific application requirements and the diffusion characteristics of the solubility-shifting agents to be employed. The recesses 114 are self-aligned to the TSVs 104, ensuring precise positioning for subsequent self-aligned processing steps.

In FIG. 1C, a polymer material 116 is deposited over the backside surface of the substrate 102 and fills the recesses 114 (see FIG. 1B). The polymer material 116 may comprise a polymer matrix and an agent-generating ingredient 118 that serves as a source for solubility-shifting agents in subsequent processing steps. The polymer matrix may include compounds such as one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbonmenes; or the like.

In various embodiments, the agent-generating ingredient 118 may comprise a TAG that releases acid upon thermal activation. TAGs may include compounds such as cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-l, 3, 5-triazine-2, 4, 6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6- trimethylbenzene sulfonic acid, triisopropylnaphthalene sulfonic acid, 5-nitro-o- toluene sulfonic acid, 5-sulfosalicylic acid, 2,5-dimethylbenzene sulfonic acid, 2- nitrobenzene sulfonic acid, 3 -chlorobenzene sulfonic acid, 3 -bromobenzene sulfonic acid, 2-fluorocaprylnaphthalene sulfonic acid, dodecylbenzene sulfonic acid, 1- naphthol-5- sulfonic acid, 2-methoxy-4-hydroxy-5-benzoyl-benzene sulfonic acid, or their salts, or combinations thereof, or the like.

In other embodiments, the agent-generating ingredient 118 may comprise a PAG that releases acid upon exposure to electromagnetic radiation. PAGs can include a diazonium salt, a phosphonium salt, a sulfonium salt, an iodonium salt, imidosulfonate, oxime sulfonate, diazodisulfone, disulfone, and o-nitrobenzyl sulfonate.

Suitable classes of PAGs generating sulfonic acids can include, but are not limited to, sulfonium or iodonium salts, oximidosulfonates, bissulfonyldiazomethanes, and nitrobenzylsulfonate esters, for example. The PAG can be in non-polymerized or polymeric form, for example, present in a polymerized repeating unit of the polymer matrix. Suitable photoacid generator compounds are disclosed, for example, in U.S. Patent 5,558,978, U.S. Patent 5,468,589, U.S. Patent 6,844,132, U.S. Patent 6,855,476, and U.S. Patent 6,911,297, which are incorporated herein by reference in their entireties. In some embodiments, a preferred PAGs can include one or more of tris(perfluoroalkylsulfonyl)methides, tris(perfluoroalkylsulfonyl)imides, and those generating perfluoroalkylsulfonic acids, for example.

Additional examples of suitable PAGs can include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts can include, but are not limited to, diphenyl iodonium perfluorobutanesulfonate, bis-(t-butylphenyl)iodonium perfluorobutanesulfonate, bis-(t-butylphenyl)iodonium, perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate.

Examples of tris(perfluoroalkylsulfonyl)methide and tris(perfluoroalkylsulfonyl)imide PAGs can be found in U.S. Patent 5,554,664 and U.S. Patent 6,306,555, each of which is incorporated herein in its entirety. In an embodiment, additional examples of PAGs of this type can be found in Proceedings of SPIE, Vol. 4690, pp. 817-828 (2002).

Suitable methide and imide PAGs can include, but are not limited to, triphenylsulfonium tris(trifluoromethylsulfonyl)methide, methylphenyldiphenylsulfonium tris(perfluoroethylsulfonyl)methide, triphenylsulfonium tris(perfluorobutylsulfonyl)methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

Further examples of suitable photoacid generators can be bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate.

Some more preferred PAGs can be triarylsulfonium perfluoroalkylsulfonates and triarylsulfonium tris(perfluoroalkylsulfonyl)methides. Some more preferred PAGs can include triphenylsulfonium perfluorooctanesulfonate (TPS-PFOS), triphenylsulfonium perfluorobutanesulfonate (TPS-Nonaflate), methyiphenyldiphenylsulfonium perfluorooctanesulfonate (TDPS-PFOS), tris(-t-butylphenyl)sulfonium perfluorobutanesulfonate (TTBPS-Nonaflate), triphenylsulfonium tris(trifluoromethylsulfonyl)methide (TPS-C1), or methylphenyldiphenylsulfonium tris(perfluoroethylsulfonyl)methide.

Additional PAG compounds can include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, or di-t-butyphenyliodonium camphorsulfonate.

Non-ionic sulfonates and sulfonyl compounds can function as photoacid generators, for example: nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; or halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Suitable non-polymerized photoacid generators that can be used are further described in U.S. Patent 8,431,325 to Hashimoto et al. in column 37, lines 11-47 and columns 41-91. Other suitable sulfonate PAGs can include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Patent 4,189,323 and U.S. Patent 8,431,325. PAGs that are onium salts typically can include an anion having a sulfonate group or a non-sulfonate type group, such as a sulfonamidate group, a sulfonimidate group, a methide group, or a borate group.

In an embodiment, a photoresist composition may optionally include a plurality of PAGs. The plural PAGs can be polymeric, non-polymeric, or can include both polymeric and non-polymeric PAGs. In some embodiments, each of the plurality of PAGs can be non-polymeric. In some embodiments, when a plurality of PAGs are used, a first PAG can include a sulfonate group on the anion and a second PAG can include an anion that is free of sulfonate groups, such anion containing for example, a sulfonamidate group, a sulfonimidate group, a methide group, or a borate group, such as described above, for example.

In some embodiments, the PAG can be a polymeric PAG, wherein the compound capable of generating an acid upon irradiation with actinic rays or radiation is introduced into the main or side chain of the polymer. Examples can include, for example, PAG compounds described in U.S. Patent 3,849,137, German Patent 3,914,407, JP-A-63-26653, JP-A-55-164824, JP-A-62-69263, JP-A-63-146038, JP-A-63-163452, JP-A-62-153853, and JP-A-63-146029.

In some embodiments, a photoresist composition can include a non-polymerized photoacid generator in an amount from about 1 to 65 wt %, from about 5 to 55 wt %, or from about 8 to 30 wt %, based on total solids of the photoresist composition, for example. In some embodiments, a photoresist composition can include two or more different non-polymerized photoacid generators in a combined amount from about 1 to 65 wt %, from about 5 to 55 wt %, or from about 8 to 30 wt %, based on total solids of the photoresist composition, for example. In some embodiments, a photoacid generator mixture can include two or three photoacid generators. Such mixtures can be of a same class or different classes. Examples of some preferred mixtures can include sulfonium salts with bis-sulfonyldiazomethane compounds, sulfonium salts and imidosulfonates, and two sulfonium salts, for example.

In some embodiments, the selection of PAGs enables photo-selective activation of specific polymer plugs. In one or more embodiments, the agent-generating ingredient 118 may comprise solubility-shifting agent (e.g., acid) itself. The solubility-shifting agent (e.g., acid) may be incorporated directly into the polymer matrix of the polymer material 116.

In various embodiments, the polymer material 116 may comprise photoresist materials, spin-on polymers, or the like, and may be deposited using spin-coating techniques. The polymer formulation may include solvents to solubilize the components during deposition, with the solvents being removed during subsequent baking or curing steps. The polymer material 116 may also include additional components such as quenchers, stabilizers, or other additives to control the diffusion and reaction characteristics of solubility-shifting agents. Quenchers may be included to limit the diffusion distance of generated acids, providing improved control over the spatial extent of solubility changes in subsequent processing steps.

In FIG. 1D, the polymer material 116 is planarized to form discrete polymer plugs 116P within the recesses 114 (see FIG. 1B), while the backside surface of the substrate 102 is exposed. The planarization process removes excess polymer material 116 from the backside surface of the substrate 102 while retaining the material within the recesses 114. After performing the planarization process, a top surface of the polymer material 116 is substantially level or coplanar with the backside surface of the substrate 102 within process variations of the planarization process.

In some embodiments, the planarization may be accomplished through CMP. The chemical mechanical planarization process may employ slurries containing abrasive particles and chemical etchants specifically formulated for the polymer material 116. In other embodiments, the planarization may be performed using etch-back techniques such as plasma etching or reactive ion etching. These dry etching processes can provide improved control over the removal rate and selectivity between the polymer material 116 and the substrate 102. The etch-back process may utilize oxygen-based plasmas, fluorine-based chemistries, or other reactive species depending on the specific polymer composition.

In FIG. 1E, an overcoat layer 120 is deposited over the backside surface of the substrate 102 and the polymer material 116. The overcoat layer 120 serves as a material that will undergo selective solubility changes in localized regions based on diffusion of solubility-shifting agents from the underlying polymer plugs 116P in subsequent processing steps. In various embodiments, the overcoat layer 120 may comprise photoresist materials, polymer resins, or other organic materials that comprise chemical deprotection (e.g., acid-cleavable) groups. These deprotection groups provide a solubility switch mechanism that responds to the presence of acids or other solubility-shifting agents. The overcoat layer 120 may also include quenchers, stabilizers, or other additives to control the interaction with diffusing solubility-shifting agents and to provide process stability during subsequent manufacturing steps. In some embodiments, the overcoat layer 120 may include the polymer matrix comprising compounds such as one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbonmenes; or the like.

In one or more embodiments, the overcoat layer 120 may be deposited using solvents that provide immiscibility with the underlying polymer material 116. This immiscibility prevents dissolution of the polymer plugs 116P during overcoat deposition, preserving the agent-generating ingredient 118 for subsequent activation. The selection of compatible solvent systems ensures that the overcoat layer 120 can be deposited without washing away or chemically altering the polymer material 116. In some embodiments, the overcoat layer 120 may be deposited using spin-coating techniques, chemical vapor deposition (CVD), or the like.

In FIG. 1F, activation energy 122 is applied to the semiconductor structure 100 to generate solubility-shifting agents 124 (represented by H+ in FIG. 1F) from the agent-generating ingredient 118 within the polymer material 116. In various embodiments where the agent-generating ingredient 118 comprises TAGs, the activation energy 122 comprises thermal energy applied through baking processes. The baking temperature and duration can be controlled to achieve optimal acid generation while avoiding degradation of other materials in the structure. In an embodiment, the baking temperatures may range from 60°C to 160°C, and the baking duration may range from 15 seconds to 8 minutes depending on the specific TAG employed. The thermal processing may be performed in controlled atmospheres such as nitrogen or other inert gases to prevent oxidation or other unwanted chemical reactions.

In various embodiments where the agent-generating ingredient 118 comprises PAGs, the activation energy 122 may comprise electromagnetic radiation such as ultraviolet light, deep ultraviolet light, or other actinic radiation. The wavelength of the electromagnetic radiation is selected based on the absorption characteristics of the specific PAG used. In one or more embodiments, the exposure may be performed as a flood exposure that activates all polymer plugs 116P simultaneously across the semiconductor structure 100. In other embodiments, patterned exposure through reticles or masks may be employed to selectively activate specific polymer plugs 116P while leaving others inactive, enabling photo-selectable contact formation for electrical routing applications.

In FIG. 1G, the solubility-shifting agents 124 diffuse (indicated by arrows 126 in FIG. 1G) from the polymer material 116 into the overlying overcoat layer 120. The diffusion process may be enhanced by a thermal treatment, which increases the mobility of the solubility-shifting agents 124 within the materials. The solubility-shifting agents 124 interact with deprotection groups within the overcoat layer 120, initiating chemical reactions that alter the solubility characteristics of localized regions. In various embodiments, the deprotection groups may comprise acid-labile groups, for example: tertiary alkyl ester groups, secondary or tertiary aryl ester groups, secondary or tertiary ester groups having a combination of alkyl and aryl groups, tertiary alkoxy groups, acetal groups, ketal groups, or the like. Upon exposure to the solubility-shifting agents 124, the acid-labile groups undergo cleavage reactions that change the polarity and solubility of the polymer chains in the overcoat layer 120.

In some embodiments when the solubility-shifting agents 124 is generated by thermal activation using a first thermal treatment, the diffusion process may be promoted or enhanced by continuing the first thermal treatment. In other embodiments when the solubility-shifting agents 124 is generated by thermal activation using a first thermal treatment, the diffusion process may be promoted or enhanced by a second thermal treatment, such that the second thermal treatment has different process parameters (e.g., temperature, duration, etc.) than the first thermal treatment.

The diffusion of the solubility-shifting agents 124 creates self-aligned regions (see FIG. 1H) of altered chemistry directly above each polymer plug 116P, establishing precise spatial registration for subsequent patterning operations. The extent of diffusion is controlled by factors including the concentration of solubility-shifting agents 124, diffusion time, temperature, and the presence of quenchers or other diffusion-limiting species. In one or more embodiments, quenchers may be incorporated into the overcoat layer 120 to limit the diffusion distance and provide better control over the spatial extent of the chemical changes. By adjusting these parameters, the dimensions and profiles of the resulting deprotected regions can be fine-tuned. The self-alignment aspect of this process comes from the fact that the source of the solubility-shifting agents 124 is the polymer material 116, which is confined to the recesses 114 (see FIG. 1B). This ensures that the pattern formed in the overcoat layer 120 will be aligned with the underlying TSVs 104.

In FIG. 1H, the semiconductor structure 100 is depicted after the solubility-shifting agent diffusion process has completed. The solubility-shifting agent 124 (shown in FIG. 1G) that was generated in the polymer layer 116 has diffused into the overcoat layer 120, creating deprotected regions 128 in the overcoat layer 120. The deprotected regions 128 represent areas where deprotection groups within the overcoat layer 120 have undergone chemical cleavage or modification reactions, resulting in changed solubility characteristics relative to predetermined developers. The remaining portions of the overcoat layer 120 that have not been exposed to significant concentrations of solubility-shifting agents 124 retain their original chemical composition and solubility characteristics.

The deprotected regions 128 in the overcoat layer 120 extend upward and laterally from interfaces with the polymer material 116, following the isotropic diffusion pattern of the solubility- shifting agent 124 (shown in FIG. 1G). A boundary of a deprotected region 128 forms a curved or semi-spherical profile, characteristic of an isotropic diffusion process. The extent of the deprotection may be determined by how far the solubility-shifting agent 124 (shown in FIG. 1G) has diffused, which may be controlled by parameters such as diffusion time, temperature, and the specific compositions of the materials involved.

The pattern formed by the deprotected regions 128 is self-aligned with the underlying polymer plugs 116P and TSVs 104 due to the confinement of the solubility-shifting agent source to the recesses 114 (see FIG. 1B), ensuring improved spatial alignment without relying on lithographic alignment techniques. This self-alignment mechanism allows for improved positioning of the pattern regardless of any minor misalignments in the exposure process used for solubility-shifting agent generation.

In FIG. 1I, the deprotected regions 128 (see FIG. 1H) of the overcoat layer 120 and the polymer material 116 (see FIG. 1H) are selectively removed, creating recesses 130 that extend through the overcoat layer 120 and into the substrate 102. In various embodiments, the removal process may utilize one or more developers comprising of a quaternary ammonium hydroxide in an aqueous solution (e.g., TMAH), water, sodium hydroxide in an aqueous solution, potassium hydroxide in an aqueous solution, n-butyl acetate (NBA), 2-heptanone, a combination thereof, or the like.

In one embodiment, the removal process may utilize a single developer that dissolves both the polymer material 116 and the deprotected regions 128 simultaneously. In another embodiment, the removal process may be performed in sequential steps to provide improved process control. The deprotected regions 128 may first be removed using a first developer specifically formulated for the deprotected regions 128, followed by removal of the polymer material 116 using a second developer different from the first developer. This sequential approach enables independent optimization of removal rates for each material and may provide better control over the final opening dimensions.

The recesses 130 expose the conductive materials 106 within the TSVs 104, establishing direct electrical access for subsequent metallization processes. The self-aligned nature of the recesses 130 ensures that the openings are precisely positioned over the conductive materials 106, reducing or eliminating overlay tolerance issues that would otherwise complicate the connection process. The bottom of each recess 130 provides a landing area for subsequent conductive features.

The lateral dimensions of the recesses 130 correspond to the extent of the deprotected regions 128 (see FIG. 1H), which were determined by the diffusion characteristics of the solubility-shifting agents 124 (see FIG. 1G) during the earlier processing steps. In one or more embodiments, the recess dimensions may be controlled through process parameters such as developer concentration, development time, and temperature. Stronger developer concentrations or longer development times may result in slightly larger openings through enhanced dissolution of partially deprotected regions at the boundaries of the deprotected regions 128.

In FIG. 1J, a pattern-reversing material 132 is formed in the recesses 130 (see FIG. 1I) of the semiconductor structure 100. The pattern-reversing material 132 may comprise a material that is different from the overcoat layer 120, the liner 108, and the substrate 102, providing etch selectivity in subsequent processing steps. In some embodiments, the pattern-reversing material 132 may comprise a material such as polymer, amorphous carbon, silicon nitride, silicon carbide, silicon oxynitride, or another suitable material with appropriate etch selectivity relative to the surrounding materials. In an embodiment, the pattern-reversing material 132 may comprise thermally decomposable polymers. The pattern-reversing material 132 may be deposited using techniques such as CVD, spin coating, a combination thereof, or the like.

In some embodiments, a planarization process may be performed to remove excess portions of the pattern-reversing material 132 extending over a top surface of the overcoat layer 120. After performing the planarization process, a top surface of the pattern-reversing material 132 is substantially level or coplanar with the top surface of the overcoat layer 120 within process variations of the planarization process. In an embodiment, the planarization process may comprise CMP, etch-back process, a combination thereof, or the like.

In FIG. 1K, the overcoat layer 120 is selectively removed while preserving the pattern-reversing material 132, creating a structure where the pattern-reversing material 132 extends above the backside surface of the substrate 102 as discrete features. The removal process exposes the substrate 102 surface between the pattern-reversing material 132 features, creating a structure with alternating regions of the exposed substrate 102 and the pattern-reversing material 132. The removal process exploits the differential solubility or etch characteristics between the overcoat layer 120 and the pattern-reversing material 132. In various embodiments, the overcoat layer 120 may be removed using solvents that selectively dissolve the overcoat material while leaving the pattern-reversing material 132 intact. The solvents may include n-butyl acetate (NBA), 2-heptanone, 1-hexanol, 2-hexanol, 4-methyl-2-pentanol, 1-pentanol, 3-methyl-1-butanol, 1-butanol, 2-butanol, 1-propanol, 2-propanol, a combination thereof, or the like.

In other embodiments, the overcoat layer 120 may be removed through plasma etching or reactive ion etching processes that provide selectivity between the overcoat material and the pattern-reversing material 132. The etch chemistry may include oxygen, nitrogen, hydrogen, or combinations thereof, with process conditions optimized to achieve high selectivity ratios and uniform removal across the semiconductor structure 100.

In FIG. 1L, a dielectric layer 134 is formed over the backside surface of the substrate 102 and adjacent to the pattern-reversing material 132. The dielectric layer 134 serves as an insulating material that will provide electrical isolation for subsequent metallization structures and define the interconnect architecture for the backside connections. In some embodiments, the dielectric layer 134 may comprise low-k dielectric materials such as fluorinated silicon glass, carbon-doped oxides, or porous materials with reduced dielectric constants. In other embodiments, the dielectric layer 134 may comprise silicon oxide silicon nitride, silicon oxynitride, or the like. The dielectric layer 134 may be deposited using CVD, atomic layer deposition (ALD), spin coating, a combination thereof, or the like.

In some embodiments, a planarization process may be performed to remove excess portions of the dielectric layer 134 extending over a top surface of the pattern-reversing material 132. After performing the planarization process, the top surface of the pattern-reversing material 132 is substantially level or coplanar with a top surface of the dielectric layer 134 within process variations of the planarization process. In an embodiment, the planarization process may comprise CMP, etch-back process, a combination thereof, or the like.

In FIG. 1M, the pattern-reversing material 132 (see FIG. 1L) is selectively removed to create recesses 136 in the dielectric layer 134 that extend down to the conductive materials 106 of the TSVs 104. The removal process may exploit the differential solubility, thermal decomposition characteristics, or etch selectivity between the pattern-reversing material 132 and the dielectric layer 134. In some embodiments where the pattern-reversing material 132 comprises thermally decomposable polymers, the removal may be accomplished through thermal processing at elevated temperatures that cause the organic material to decompose and volatilize while leaving the dielectric layer 134 intact.

In some embodiments where the pattern-reversing material 132 comprises an organic material, the pattern-reversing material 132 may be removed using selective solvents that dissolve the organic material without significantly affecting the dielectric layer 134. The solvents may include comprising of a quaternary ammonium hydroxide in an aqueous solution (e.g., TMAH), water, sodium hydroxide in an aqueous solution, potassium hydroxide in an aqueous solution, n-butyl acetate (NBA), 2-heptanone, 1-hexanol, 2-hexanol, 4-methyl-2-pentanol, 1-pentanol, 3-methyl-1-butanol, 1-butanol, 2-butanol, 1-propanol, 2-propanol, a combination thereof, or the like. The solvent selection depends on the specific composition of the pattern-reversing material 132 and the chemical resistance of the dielectric layer 134. In other embodiments, the removal process may utilize plasma etching or reactive ion etching with chemistries that selectively remove pattern-reversing material 132.

The recesses 136 are self-aligned to the TSVs 104, maintaining the precise spatial alignment established through the earlier chemical self-alignment process. The lateral dimensions of the recesses 136 correspond to the cross-sectional area of the removed pattern-reversing material 132 (see FIG. 1L), which was determined by the diffusion characteristics of the solubility-shifting agents during the initial patterning steps. This self-aligned nature reduces or eliminates overlay tolerance issues that would otherwise complicate the formation of electrical connections to the underlying TSVs 104.

In FIG. 1N, conductive features 138 are formed within the recesses 136 (see FIG. 1M), establishing electrical connections between the TSVs 104 and subsequently formed overlying interconnect structures. In some embodiments, the conductive features 138 may be formed using a damascene process. In an embodiment, each of the conductive features 138 comprises a conductive material 142 and a barrier layer 140 lining sidewalls and a bottom of the conductive material 142. In another embodiment, the barrier layer 140 may be omitted. The barrier layer 140 may comprise tantalum, tantalum nitride, titanium, titanium nitride, combinations thereof, or the like, and may be deposited using ALD, CVD, physical vapor deposition (PVD), a combination thereof, or the like. In various embodiments, the conductive material 142 may comprise copper, aluminum, tungsten, cobalt, ruthenium, molybdenum, alloys thereof, or the like, and may be formed using electroplating, electroless plating, CVD, PVD, a combination thereof, or the like.

In some embodiments, a planarization process may be performed to remove excess portions of the conductive material 142 and the barrier layer 140 extending over the top surface of the dielectric layer 134. After performing the planarization process, top surfaces of the conductive features 138 are substantially level or coplanar with the top surface of the dielectric layer 134 within process variations of the planarization process. In an embodiment, the planarization process may comprise CMP, etch-back process, a combination thereof, or the like.

In some embodiments, a backside power distribution network 144 is formed over the dielectric layer 134 and connected to the conductive features 138. The backside power distribution network 144 comprises interconnect structures that distribute power and ground signals to the various circuit elements within the semiconductor structure 100. In various embodiments, the backside power distribution network 144 may comprise multiple metallization levels with power rails, ground planes, and signal routing structures formed using damascene or subtractive metallization techniques. The conductive features 138 may be considered as a part of the backside power distribution network 144.

The backside power distribution network 144 enables power delivery to the active devices within the device layer 110 through the self-aligned connections established by the conductive features 138 and TSVs 104. In some embodiments, the backside power distribution network 144 may include decoupling capacitors, voltage regulators, or other power management circuits integrated into the backside metallization layers. These integrated power management features can provide localized power conditioning and improve overall system performance. The self-aligned nature of the conductive features 138 ensures reliable electrical connections without the overlay tolerance limitations associated with conventional lithographic alignment techniques.

FIGS. 1O-1Q illustrate cross-sectional views of intermediate stages in planarizing the polymer material 116 of FIG. 1C, in accordance with various embodiments. In FIG. 1O, an overcoat layer 146 is formed over the structure of FIG. 1C. In some embodiments, the overcoat layer 146 may be deposited over the polymer material 116 using a spin coating method. In some embodiments, the overcoat layer 146 may comprise a polymer matrix and an agent-generating ingredient 148 that serves as a source for solubility-shifting agents in subsequent processing steps. In some embodiments, the polymer matrix may include monomers with ethylenically unsaturated polymerizable double bonds, including (meth)acrylate monomers; (meth)acrylic acids; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbornenes; and combinations thereof. In other embodiments, the polymer matrix may include monomers comprising one or more functional groups chosen from hydroxy, carboxyl, sulfonic acid, sulfonamide, silanol, fluoroalcohol, anhydrates, lactones, esters, ethers, allylamine, pyrrolidones, and combinations thereof.

In various embodiments, the agent-generating ingredient 148 may comprise one or more TAGs that release acid upon thermal activation. The TAGs of the overcoat layer 146 may be similar to the TAGs of the polymer material 116 and the description is not repeated herein. In other embodiments, the agent-generating ingredient 148 may comprise one or more PAGs that release acid upon exposure to electromagnetic radiation. The PAGs of the overcoat layer 146 may be similar to the PAGs of the polymer material 116 and the description is not repeated herein. In yet other embodiments, the agent-generating ingredient 148 may comprise solubility-shifting agent (e.g., acid) itself. The solubility-shifting agent (e.g., acid) may be incorporated directly into the polymer matrix of the overcoat layer 146.

In FIG. 1P, activation energy 150 is applied to the semiconductor structure 100 to generate solubility-shifting agents 152 (represented by H+ in FIG. 1P) from the agent-generating ingredient 148 within the overcoat layer 146. In various embodiments where the agent-generating ingredient 148 comprises TAGs, the activation energy 150 comprises thermal energy applied through baking processes. The baking temperature and duration can be controlled to achieve optimal acid generation while avoiding degradation of other materials in the structure. In an embodiment, the baking temperatures may range from 60 °C to 160 °C, and the baking duration may range from 15 seconds to 8 minutes depending on the specific TAG employed. The thermal processing may be performed in controlled atmospheres such as nitrogen or other inert gases to prevent oxidation or other unwanted chemical reactions.

In various embodiments where the agent-generating ingredient 148 comprises PAGs, the activation energy 150 may comprise electromagnetic radiation such as ultraviolet light, deep ultraviolet light, or other actinic radiation. The wavelength of the electromagnetic radiation is selected based on the absorption characteristics of the specific PAG used.

In FIG. 1Q, a baking process is performed where thermal energy 154 is applied to the semiconductor structure 100 to diffuse the solubility-shifting agents 152 from the overcoat layer 146 into the polymer material 116. In an embodiment, the baking temperatures may range from 60 °C to 150 °C, and the baking duration may range from 15 seconds to 5 minutes. The thermal processing may be performed in controlled atmospheres such as nitrogen or other inert gases to prevent oxidation or other unwanted chemical reactions.

The solubility-shifting agents 152 interact with the polymer material 116 to form a deprotected region 156 in the polymer material 116. In some embodiments, parameters of the baking process such as the baking temperature and the baking duration may be tuned so that the deprotected region 156 does not extend below the backside surface of the substrate 102 and as-deposited polymer material 116 remains within the recesses 114 (see FIG. 1B). In an embodiment, a bottom surface of the deprotected region 156 is above the backside surface of the substrate 102.

After forming the deprotected region 156, the overcoat layer 146 and the deprotected region 156 are selectively removed to form the structure of FIG. 1D. The overcoat layer 146 and the deprotected region 156 may be selectively removed using a suitable solvent. In an embodiment, the solvent may comprise TMAH.

FIGS. 1R and 1S illustrate cross-sectional views of intermediate stages in planarizing the polymer material 116 of FIG. 1C, in accordance with various embodiments. In FIG. 1R, activation energy 158 is applied to the semiconductor structure 100 of FIG. 1C to generate solubility-shifting agents 160 (represented by H+ in FIG. 1R) from the agent-generating ingredient 118 within the polymer material 116.

In various embodiments where the agent-generating ingredient 118 comprises PAGs, the activation energy 158 may comprise electromagnetic radiation such as ultraviolet light, deep ultraviolet light, or other actinic radiation. In some embodiments, the wavelength of the electromagnetic radiation is selected such that solubility-shifting agents are not generated in portions of the polymer material 116 that are disposed within the recesses 114 (see FIG. 1B). In an embodiment, the wavelength of the electromagnetic radiation is selected such that a diameter of the recesses 114 is less than a quarter of the wavelength.

In FIG. 1S, a baking process is performed where thermal energy 162 is applied to the semiconductor structure 100 to promote reaction between the solubility-shifting agents 160 and the polymer material 116. In an embodiment, the baking temperatures may range from 60 °C to 120 °C, and the baking duration may range from 15 seconds to 5 minutes.

The solubility-shifting agents 160 interact with the polymer material 116 to form a deprotected region 164 in the polymer material 116. In some embodiments, the deprotected region 164 does not extend below the backside surface of the substrate 102 and as-deposited polymer material 116 remains within the recesses 114 (see FIG. 1B) due to the selection of the wavelength of the electromagnetic radiation. In an embodiment, a bottom surface of the deprotected region 164 is above the backside surface of the substrate 102.

After forming the deprotected region 164, the deprotected region 164 is selectively removed to form the structure of FIG. 1D. The deprotected region 164 may be selectively removed using a suitable solvent. In an embodiment, the solvent may comprise TMAH.

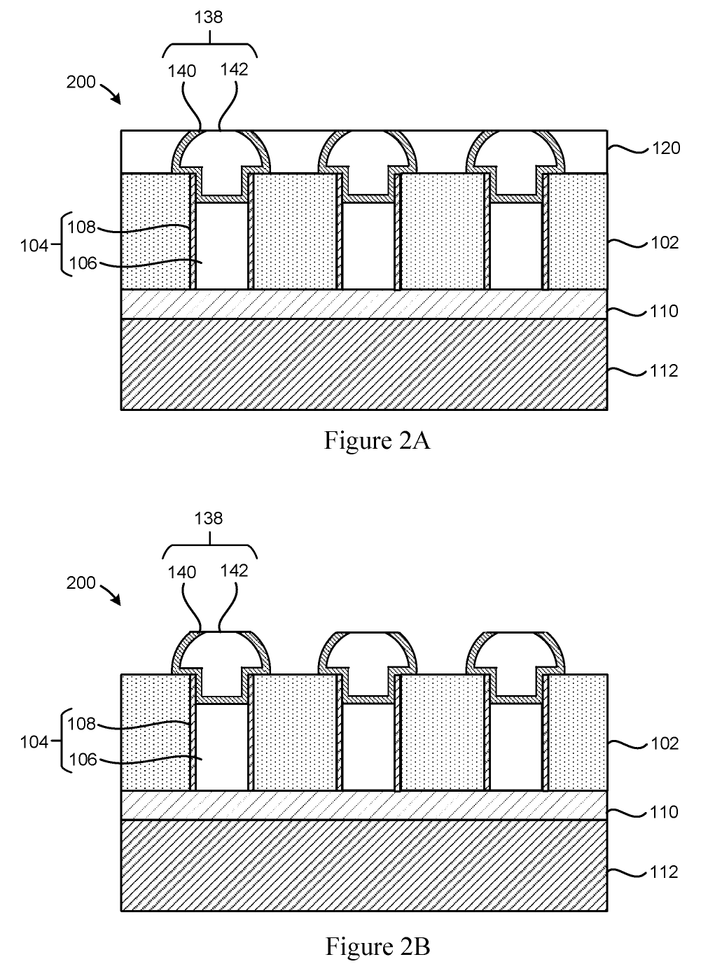

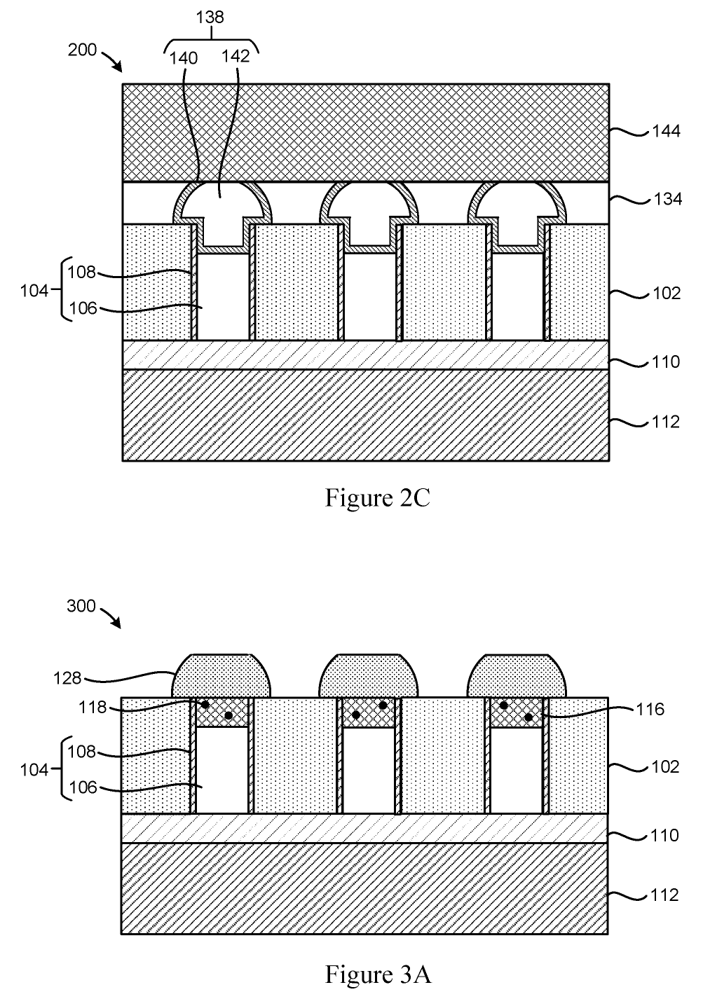

FIGS. 2A-2C illustrate cross-sectional views of intermediate stages in the manufacturing of a semiconductor structure 200, in accordance with various embodiments. In particular, FIG. 2A illustrates the semiconductor structure 200 after performing various process steps on the structure of FIG. 1I. In some embodiments, conductive features 138 are formed in the recesses 130 (see FIG. 1I) as described above with reference to FIG. 1N, and the description is not repeated herein.

In FIG. 2B, the overcoat layer 120 is selectively removed while preserving the conductive features 138, creating a structure where the conductive features 138 extend above the backside surface of the substrate 102 as discrete raised features. In some embodiments, the overcoat layer 120 may be removed as described above with reference to FIG. 1K, and the description is not repeated herein.

In FIG. 2C, a dielectric layer 134 is formed over the backside surface of the substrate 102 and surrounding the conductive features 138. In some embodiments, the dielectric layer 134 may be formed as described above with reference to FIG. 1L, and the description is not repeated herein. Subsequently, a backside power distribution network 144 is formed over the dielectric layer 134 and electrically connected to the conductive features 138 as described above with reference to FIG. 1N, and the description is not repeated herein.

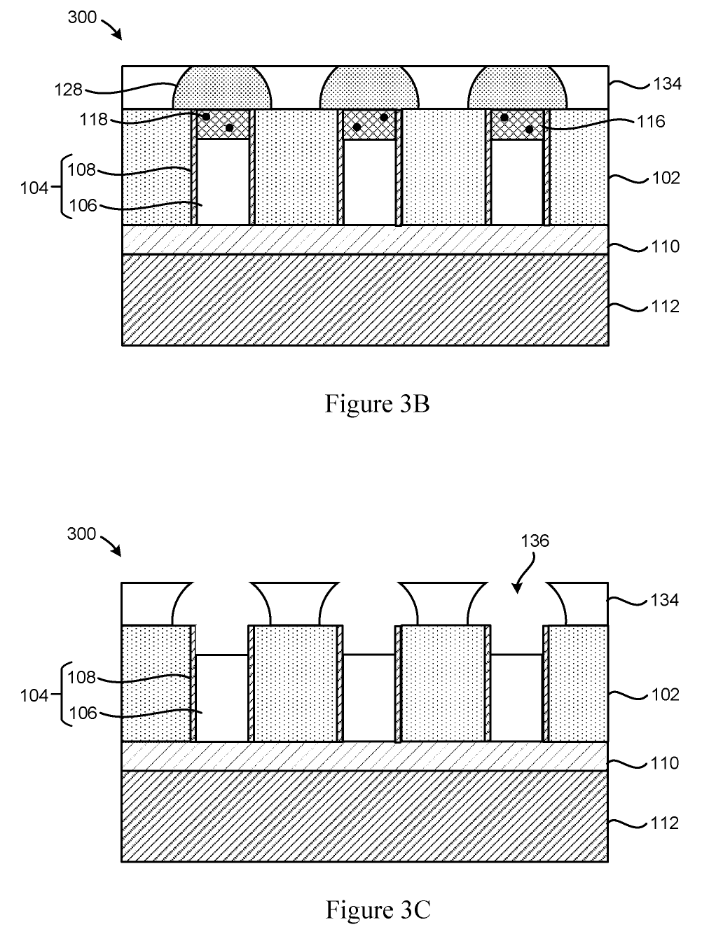

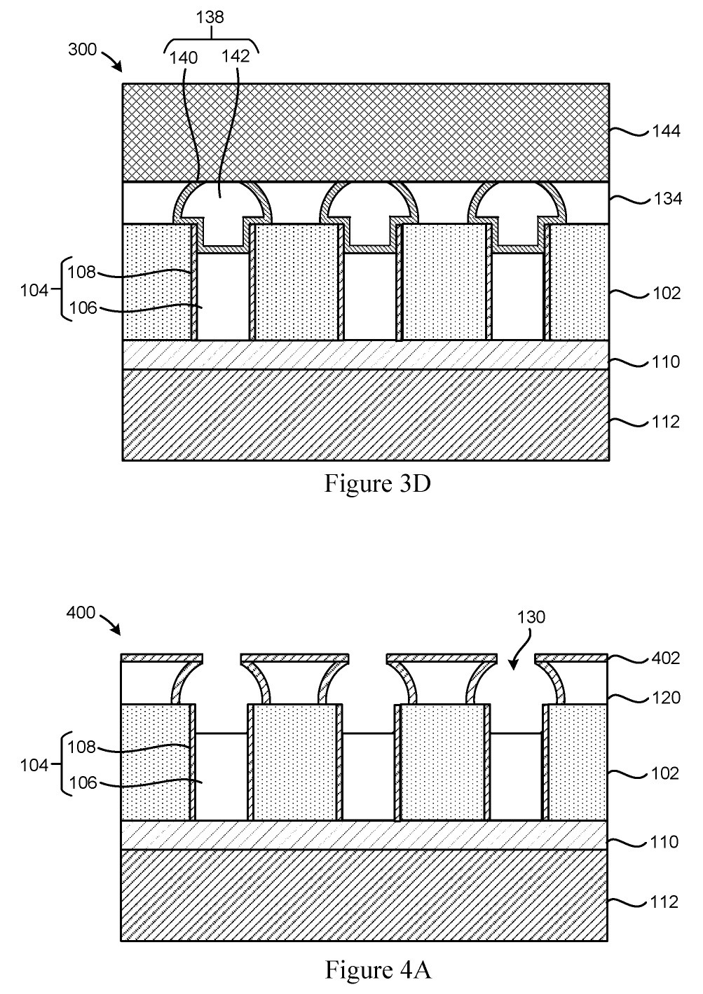

FIGS. 3A-3D illustrate cross-sectional views of intermediate stages in the manufacturing of a semiconductor structure 300, in accordance with various embodiments. In particular, FIG. 3A illustrates the semiconductor structure 300 after performing various process steps on the structure of FIG. 1H. In some embodiments, unmodified regions of the overcoat layer 120 are selectively removed while the deprotected regions 128 remain as discrete features extending above the backside surface of the substrate 102. This selective removal process exploits the differential solubility characteristics created by the diffusion of solubility-shifting agents, where the deprotected regions 128 exhibit different solubility properties compared to the unmodified portions of the overcoat layer 120. In some embodiments, the removal process may utilize solvents such as quaternary ammonium hydroxide in an aqueous solution (e.g., TMAH), water, sodium hydroxide in an aqueous solution, potassium hydroxide in an aqueous solution, n-butyl acetate (NBA), 2-heptanone, 1-hexanol, 2-hexanol, 4-methyl-2-pentanol, 1-pentanol, 3-methyl-1-butanol, 1-butanol, 2-butanol, 1-propanol, 2-propanol, a combination thereof, or the like.

In FIG. 3B, a dielectric layer 134 is formed over the backside surface of the substrate 102 and surrounding the deprotected regions 128. In some embodiments, the dielectric layer 134 may be formed as described above with reference to FIG. 1L, and the description is not repeated herein.

In FIG. 3C, the deprotected regions 128 and the polymer material 116 (see FIG. 3B) are selectively removed, creating recesses 136 that extend through the dielectric layer 134 and into the substrate 102 and expose the TSVs 104. In some embodiments, the deprotected regions 128 and the polymer material 116 may be selectively removed as described above with reference to FIG. 1I, and the description is not repeated herein.

In FIG. 3D, conductive features 138 are formed within the recesses 136 (see FIGS. 3C), establishing electrical connections between the TSVs 104 and a subsequently formed backside power distribution network. In some embodiments, the conductive features 138 are formed in the recesses 136 (see FIGS. 3C) as described above with reference to FIG. 1N, and the description is not repeated herein. Subsequently, a backside power distribution network 144 is formed over the dielectric layer 134 and electrically connected to the conductive features 138 as described above with reference to FIG. 1N, and the description is not repeated herein.

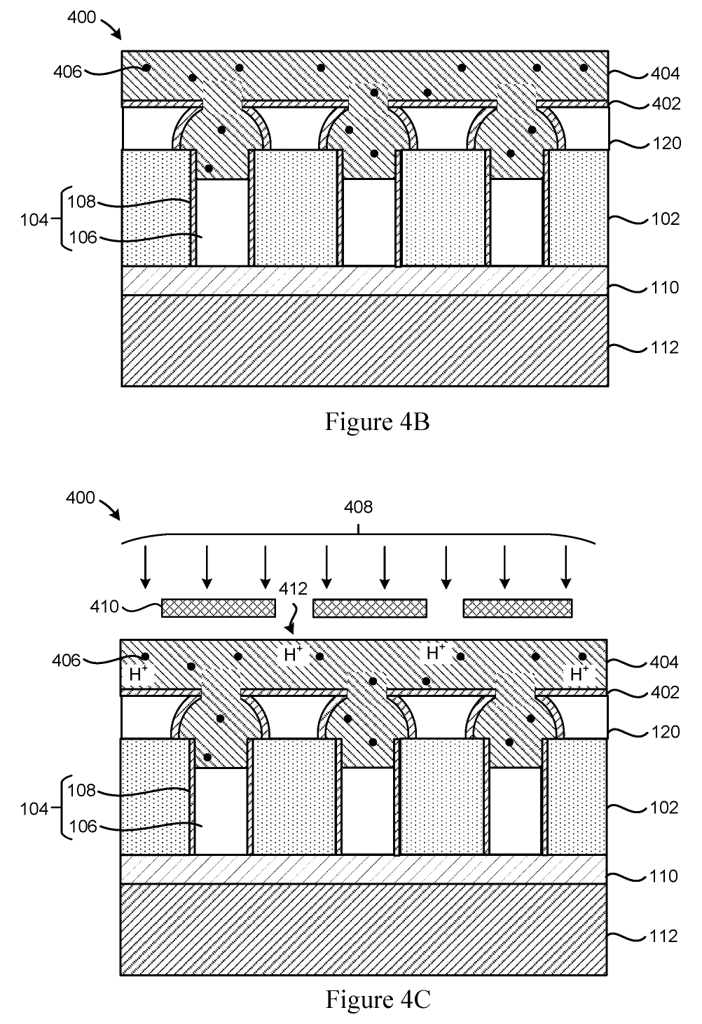

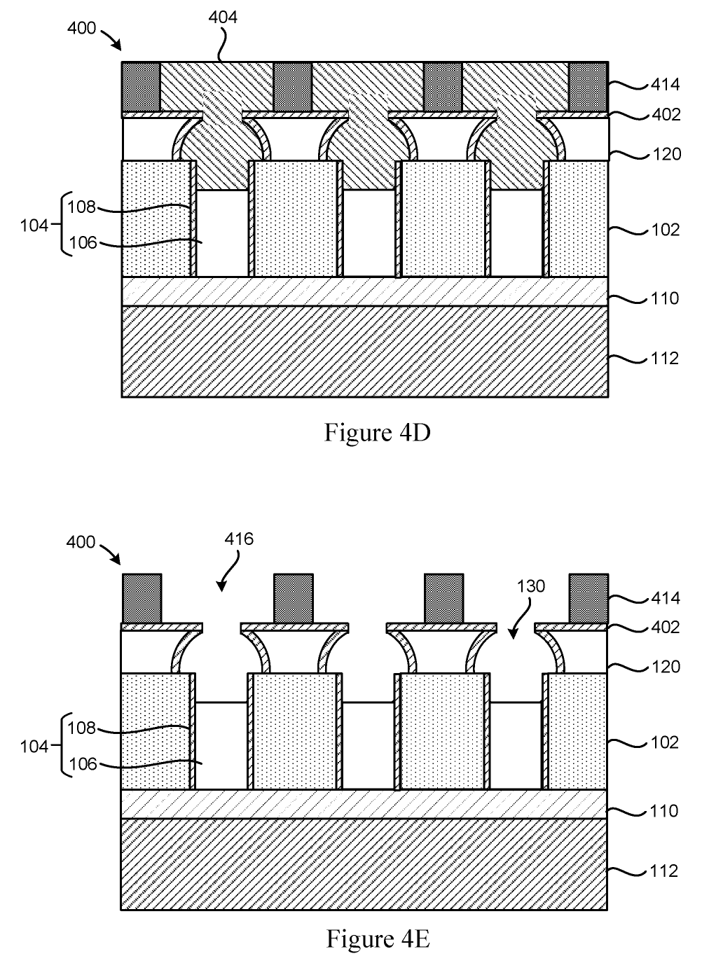

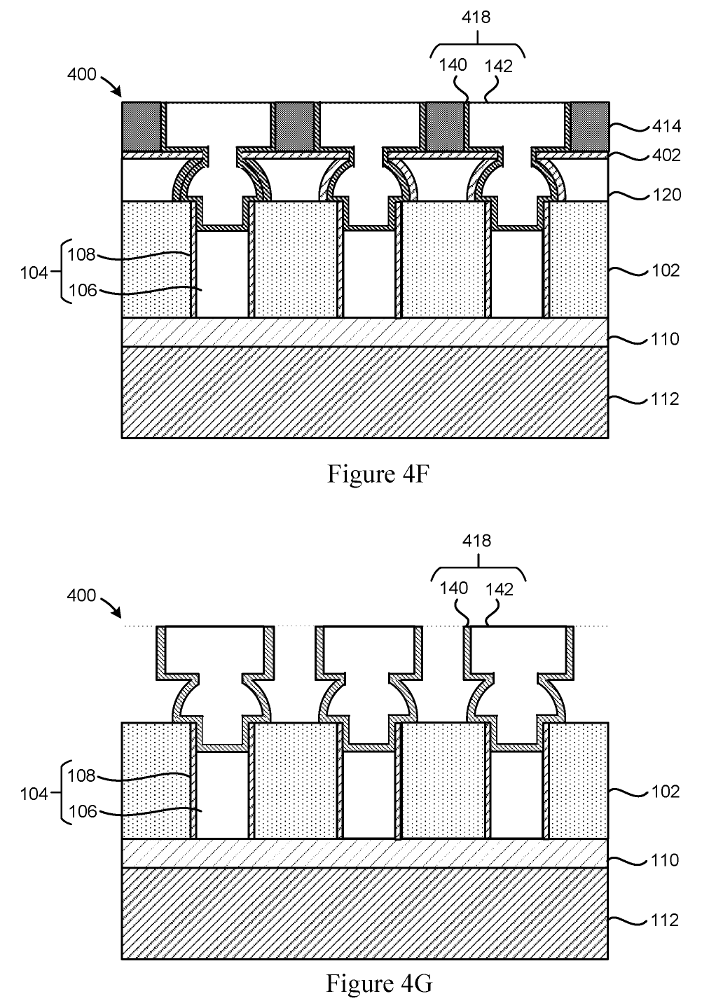

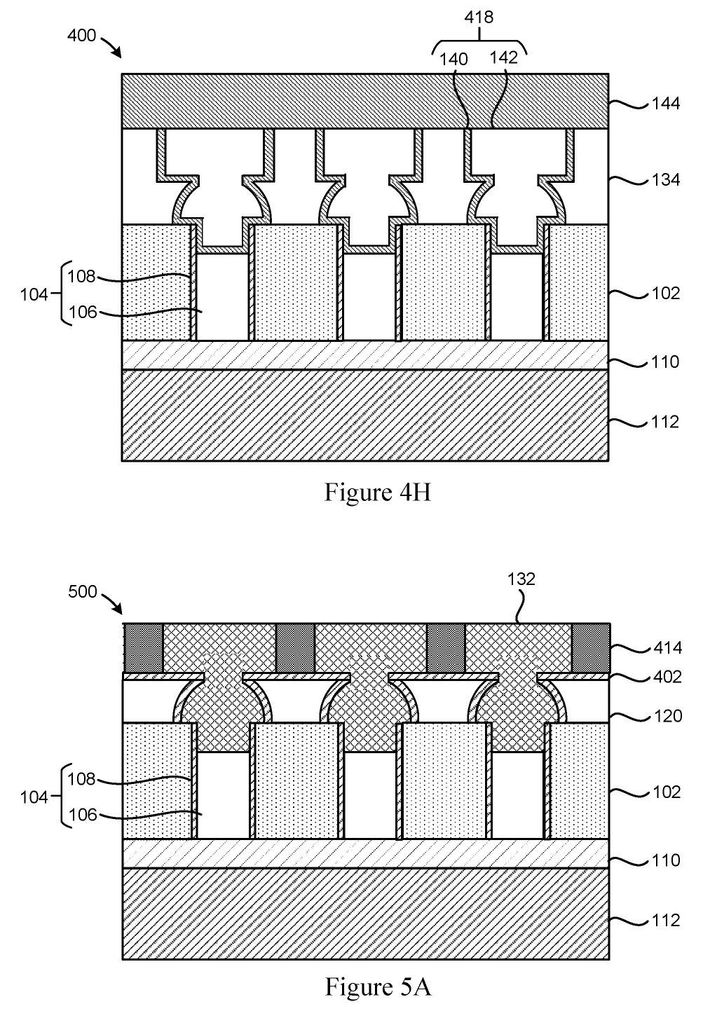

FIGS. 4A-4I illustrate cross-sectional views of intermediate stages in the manufacturing of a semiconductor structure 400, in accordance with various embodiments. In particular, FIG. 4A illustrates the semiconductor structure 400 after performing various process steps on the structure of FIG. 1I. In some embodiments, a protective layer 402 is formed on exposed surfaces of the overcoat layer 120 through a freeze process. The freeze process creates a chemically resistant surface layer that prevents unwanted dissolution or chemical modification of the overcoat layer 120 during subsequent processing steps.

In various embodiments, the freeze process may utilize plasma treatments with gases such as fluorine, chlorine, or other halogenated species that react with the overcoat layer 120. In one or more embodiments, the plasma conditions including power density, pressure, gas flow rates, and treatment time may be optimized to achieve adequate surface modification of the overcoat layer 120.

The protective layer 402 formation creates a skin effect that prevents erosion or dissolution of the overcoat layer 120 when exposed to solvents or developers used in subsequent photolithographic processes. The protective layer 402 enables subsequent processing steps such as the deposition and patterning of additional polymer layers without compromising the integrity of the overcoat layer 120.

In FIG. 4B, a polymer material 404 is deposited within the recesses 130 (see FIG. 4A) and over the protective layer 402. The polymer material 404 serves as a second polymer layer that enables additional patterning operations while maintaining the self-aligned positioning established by the original recesses 130. The polymer material 404 may comprise materials specifically formulated for compatibility with the protective layer 402 and subsequent processing requirements. In various embodiments, the polymer material 404 may comprise photoresist materials, spin-on polymers, or the like, and may be deposited using spin-coating techniques. The polymer formulation may include solvents to solubilize the components during deposition, with the solvents being removed during subsequent baking or curing steps.

In some embodiments, the polymer material 404 comprises a polymer matrix and an agent-generating ingredient 406 that serves as a source for solubility-shifting agents in subsequent processing steps. The polymer matrix may include compounds such as one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbonmenes; or the like. In various embodiments, the agent-generating ingredient 406 may comprise a TAG that releases acid upon thermal activation TAGs may include compounds such as cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-l, 3, 5-triazine-2, 4, 6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6- trimethylbenzene sulfonic acid, triisopropylnaphthalene sulfonic acid, 5-nitro-o- toluene sulfonic acid, 5-sulfosalicylic acid, 2,5-dimethylbenzene sulfonic acid, 2- nitrobenzene sulfonic acid, 3 -chlorobenzene sulfonic acid, 3 -bromobenzene sulfonic acid, 2-fluorocaprylnaphthalene sulfonic acid, dodecylbenzene sulfonic acid, 1- naphthol-5- sulfonic acid, 2-methoxy-4-hydroxy-5-benzoyl-benzene sulfonic acid, or their salts, or combinations thereof. or the like. In other embodiments, the agent-generating ingredient 406 may comprise a PAG that releases acid upon exposure to electromagnetic radiation. PAGs may include PAGs can include a diazonium salt, a phosphonium salt, a sulfonium salt, an iodonium salt, imidosulfonate, oxime sulfonate, diazodisulfone, disulfone, and o-nitrobenzyl sulfonate.

Suitable classes of PAGs generating sulfonic acids can include, but are not limited to, sulfonium or iodonium salts, oximidosulfonates, bissulfonyldiazomethanes, and nitrobenzylsulfonate esters, for example. The PAG can be in non-polymerized or polymeric form, for example, present in a polymerized repeating unit of the polymer matrix. Suitable photoacid generator compounds are disclosed, for example, in U.S. Patent 5,558,978, U.S. Patent 5,468,589, U.S. Patent 6,844,132, U.S. Patent 6,855,476, and U.S. Patent 6,911,297, which are incorporated herein by reference in their entireties. In some embodiments, a preferred PAGs can include one or more of tris(perfluoroalkylsulfonyl)methides, tris(perfluoroalkylsulfonyl)imides, and those generating perfluoroalkylsulfonic acids, for example.

Additional examples of suitable PAGs can include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts can include, but are not limited to, diphenyl iodonium perfluorobutanesulfonate, bis-(t-butylphenyl)iodonium perfluorobutanesulfonate, bis-(t-butylphenyl)iodonium, perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate.

Examples of tris(perfluoroalkylsulfonyl)methide and tris(perfluoroalkylsulfonyl)imide PAGs can be found in U.S. Patent 5,554,664 and U.S. Patent 6,306,555, each of which is incorporated herein in its entirety. In an embodiment, additional examples of PAGs of this type can be found in Proceedings of SPIE, Vol. 4690, pp. 817-828 (2002).

Suitable methide and imide PAGs can include, but are not limited to, triphenylsulfonium tris(trifluoromethylsulfonyl)methide, methylphenyldiphenylsulfonium tris(perfluoroethylsulfonyl)methide, triphenylsulfonium tris(perfluorobutylsulfonyl)methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

Further examples of suitable photoacid generators can be bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1cyclohexylcarbonyldiazomethane, 1-diazo-1-cyclohexylsulfonyl-3,3- dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate.

Some more preferred PAGs can be triarylsulfonium perfluoroalkylsulfonates and triarylsulfonium tris(perfluoroalkylsulfonyl)methides. Some more preferred PAGs can include triphenylsulfonium perfluorooctanesulfonate (TPS-PFOS), triphenylsulfonium perfluorobutanesulfonate (TPS-Nonaflate), methyiphenyldiphenylsulfonium perfluorooctanesulfonate (TDPS-PFOS), tris(-t-butylphenyl)sulfonium perfluorobutanesulfonate (TTBPS-Nonaflate), triphenylsulfonium tris(trifluoromethylsulfonyl)methide (TPS-C1), or methylphenyldiphenylsulfonium tris(perfluoroethylsulfonyl)methide.

Additional PAG compounds can include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, or di-t-butyphenyliodonium camphorsulfonate.

Non-ionic sulfonates and sulfonyl compounds can function as photoacid generators, for example: nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; or halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Suitable non-polymerized photoacid generators that can be used are further described in U.S. Patent 8,431,325 to Hashimoto et al. in column 37, lines 11-47 and columns 41-91. Other suitable sulfonate PAGs can include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Patent 4,189,323 and U.S. Patent 8,431,325. PAGs that are onium salts typically can include an anion having a sulfonate group or a non-sulfonate type group, such as a sulfonamidate group, a sulfonimidate group, a methide group, or a borate group.

In an embodiment, a photoresist composition may optionally include a plurality of PAGs. The plural PAGs can be polymeric, non-polymeric, or can include both polymeric and non-polymeric PAGs. In some embodiments, each of the plurality of PAGs can be non-polymeric. In some embodiments, when a plurality of PAGs are used, a first PAG can include a sulfonate group on the anion and a second PAG can include an anion that is free of sulfonate groups, such anion containing for example, a sulfonamidate group, a sulfonimidate group, a methide group, or a borate group, such as described above, for example.

In some embodiments, the PAG can be a polymeric PAG, wherein the compound capable of generating an acid upon irradiation with actinic rays or radiation is introduced into the main or side chain of the polymer. Examples can include, for example, PAG compounds described in U.S. Patent 3,849,137, German Patent 3,914,407, JP-A-63-26653, JP-A-55-164824, JP-A-62-69263, JP-A-63-146038, JP-A-63-163452, JP-A-62-153853, and JP-A-63-146029.

In some embodiments, a photoresist composition can include a non-polymerized photoacid generator in an amount from about 1 to 65 wt %, from about 5 to 55 wt %, or from about 8 to 30 wt %, based on total solids of the photoresist composition, for example. In some embodiments, a photoresist composition can include two or more different non-polymerized photoacid generators in a combined amount from about 1 to 65 wt %, from about 5 to 55 wt %, or from about 8 to 30 wt %, based on total solids of the photoresist composition, for example. In some embodiments, a photoacid generator mixture can include two or three photoacid generators. Such mixtures can be of a same class or different classes. Examples of some preferred mixtures can include sulfonium salts with bis-sulfonyldiazomethane compounds, sulfonium salts and imidosulfonates, and two sulfonium salts, for example. In some embodiments, the polymer material 404 may also include additional components such as quenchers, stabilizers, or other additives to control the diffusion and reaction characteristics of solubility-shifting agents.

The protective layer 402 ensures that the polymer material 404 can be deposited and processed without adversely affecting the underlying overcoat layer 120. The chemical resistance provided by the protective layer 402 prevents solvents in the polymer material 404 from dissolving or modifying the overcoat layer 120, maintaining the integrity of the structure.

In FIG. 4C, activation energy 408 is applied to the structure to generate solubility-shifting agents 412 (represented by H+ in FIG. 4C) from the agent-generating ingredient 406 within the polymer material 404. In various embodiments where the agent-generating ingredient 406 comprises PAGs, the activation energy 408 comprises electromagnetic radiation such as ultraviolet light, deep ultraviolet light, or other actinic radiation delivered through a reticle 410. The reticle 410 comprises a pattern that selectively exposes specific regions of the polymer material 404 while blocking radiation from reaching other areas. The wavelength of the electromagnetic radiation is selected based on the absorption characteristics of the specific PAG used. The reticle 410 enables control over which regions of the polymer material 404 are activated, providing spatial selectivity for the generation of solubility-shifting agents 412. The reticle pattern may be designed to create trench structures, line patterns, or other interconnect geometries.

The spatial distribution of solubility-shifting agents 412 corresponds to the pattern defined by the reticle 410, creating regions with altered solubility characteristics. The lithographic exposure process enables the creation of well-defined patterns with dimensions determined by the optical resolution of the exposure system and the characteristics of the polymer material 404.

In FIG. 4D, a thermal process has been applied to the semiconductor structure 400 to promote the formation of deprotected regions 414 within the polymer material 404. The thermal process drives acid-catalyzed deprotection reactions initiated by the solubility-shifting agents 412 (see FIG. 4C) generated in the previous exposure step, causing chemical modifications that alter the solubility characteristics of specific regions within the polymer material 404. The deprotected regions 414 represent areas where acid-labile protecting groups within the polymer material 404 have undergone cleavage reactions catalyzed by the solubility-shifting agents 412 (see FIG. 4C). In various embodiments, the thermal process may comprise post-exposure baking at a temperature ranging from 60 °C to 160 °C, with a baking time ranging from 15 seconds to 8 minutes.

The deprotected regions 414 exhibit altered solubility characteristics compared to the unexposed portions of the polymer material 404, creating differential solubility that enables selective removal in subsequent development steps. The spatial distribution of the deprotected regions 414 corresponds to the areas that were exposed to electromagnetic radiation in the previous processing step, maintaining the pattern fidelity established by the lithographic exposure process.

In FIG. 4E, unmodified regions of the polymer material 404 have been selectively removed through a development process, creating recesses 416 that expose the underlying protective layer 402 and exposing the recesses 130 that expose the TSVs 104. In some embodiments, a width of the recesses 416 is greater than a width of the recesses 130.

The development process exploits the differential solubility characteristics created by the thermal deprotection reactions, where the deprotected regions 414 exhibit significantly different solubility compared to the unmodified portions of the polymer material 404. In various embodiments when negative tone developers are used, the deprotected regions 414 become less soluble in such developers, enabling selective removal of the unmodified regions of the polymer material 404 while preserving the deprotected regions 414. The deprotected regions 414 serve as masking elements that protect the underlying overcoat layer 120 during subsequent processing operations. In an embodiment, the developers may comprise n-butyl acetate (NBA), 2-heptanone, a combination thereof, or the like. In some embodiments, the protection layer 402 protects the overcoat layer 120 from the developer.

The resulting structure contains both self-aligned recesses 130 and lithographically defined recesses 416. The self-aligned recesses 130 ensure precise connection to the underlying TSVs 104, while the recesses 416 enable the formation of interconnect routing structures with geometries defined by conventional lithographic techniques. The combination of recesses 416 and 130 demonstrates the integration of self-aligned and conventional lithographic patterning approaches, enabling the creation of complex interconnect architectures that benefit from the precision of chemical self-alignment for critical connections and the flexibility of photolithography for routing and distribution networks.

In FIG. 4F, conductive features 418 are formed within both the self-aligned recesses 130 and the lithographically defined recesses 416. In an embodiment, each of the conductive features 418 comprises a conductive material 142 and a barrier layer 140 lining sidewalls and a bottom of the conductive material 142. In another embodiment, the barrier layer 140 may be omitted. In some embodiments, the conductive features 418 may be formed in a similar manner as the conductive features 138 as described above with reference to FIG. 1N, and the description is not repeated herein.

Portions of the conductive features 418 in the self-aligned recesses 130 (see FIG. 4E) establish direct electrical contact with the conductive materials 106 within the TSVs 104. The self-aligned nature of these connections reduces or eliminates overlay tolerance issues and ensures consistent electrical contact regardless of minor variations in processing conditions. Portions of the conductive features 418 in the lithographically defined recesses 416 (see FIG. 4E) provide interconnect routing structures that can distribute signals, power, or ground connections across the backside surface of the substrate 102.

In FIG. 4G, the deprotected regions 414, the protective layer 402, and the overcoat layer 120 are selectively removed while preserving the conductive features 418, creating a structure where the conductive features 418 extend above the backside surface of the substrate 102 surface as discrete raised interconnect elements. In some embodiments, the deprotected regions 414, the protective layer 402, and the overcoat layer 120 may be selectively removed by one or more solvents. In some embodiments, the one or more solvents may comprise 1-hexanol, 2-hexanol, 4-methyl-2-pentanol, 1-pentanol, 3-methyl-1-butanol, 1-butanol, 2-butanol, 1-propanol, 2-propanol, a combination thereof, or the like.

In one embodiment, the removal process may utilize a single solvent that dissolves the deprotected regions 414, the protective layer 402, and the overcoat layer 120 simultaneously. In another embodiment, the removal process may be performed in sequential steps to provide improved process control. The deprotected regions 414 may first be removed using a first solvent specifically formulated for the deprotected regions 414, followed by removal of the protective layer 402 using a second solvent that is different from the first solvent, followed by removal of the overcoat layer 120 using a third solvent that is different from the first solvent and/or the second solvent.

In FIG. 4H, a dielectric layer 134 is formed over the substrate 102 and surrounding the conductive features 418. In some embodiments, the dielectric layer 134 may be formed as described above with reference to FIG. 1L, and the description is not repeated herein. Subsequently, a backside power distribution network 144 is formed over the dielectric layer 134 and electrically connected to the conductive features 418 as described above with reference to FIG. 1N, and the description is not repeated herein. The conductive features 418 may be considered as a part of the backside power distribution network 144.

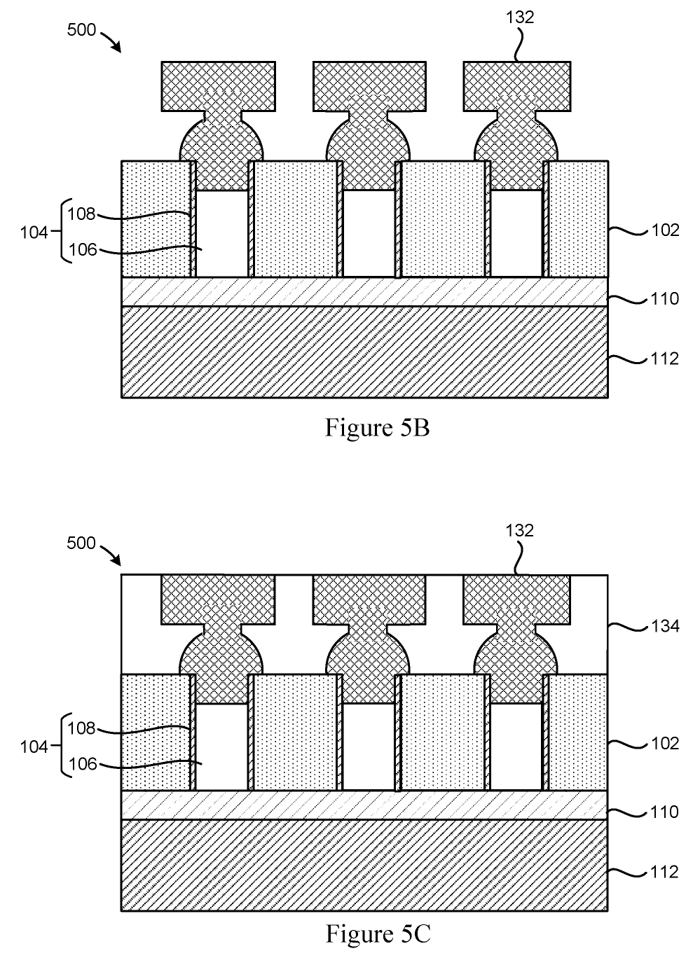

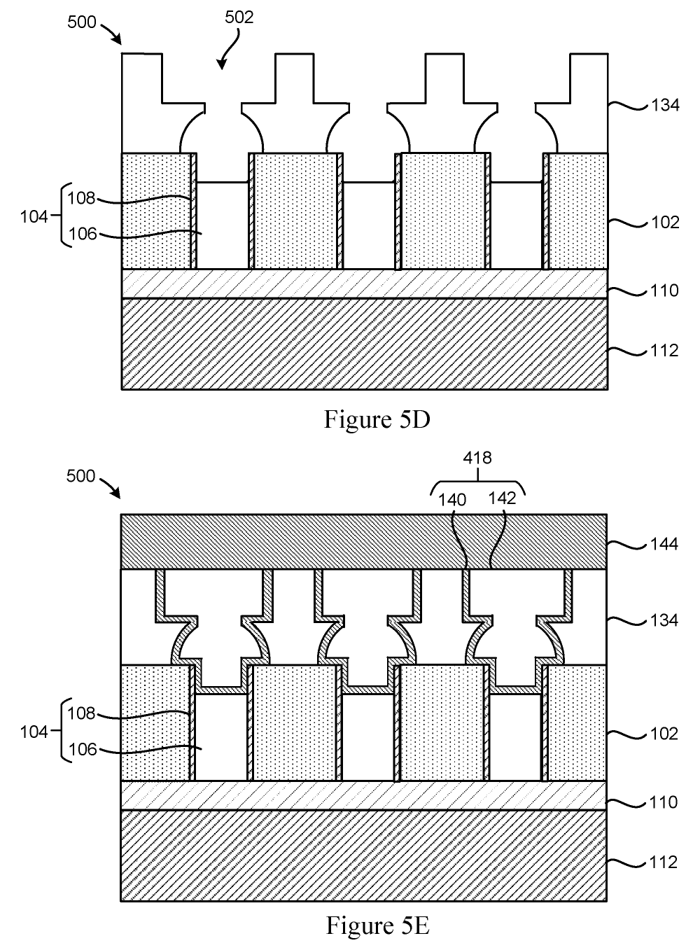

FIGS. 5A-5E illustrate cross-sectional views of intermediate stages in the manufacturing of a semiconductor structure 500, in accordance with various embodiments. In particular, FIG. 5A illustrates the semiconductor structure 500 after performing various process steps on the structure of FIG. 4E. In some embodiments, a pattern-reversing material 132 is deposited within both the self-aligned recesses 130 and the lithographically defined recesses 416 (see FIG. 4E) as described above with reference to FIG. 1J, and the description is not repeated herein.

In FIG. 5B, the deprotected regions 414, the protective layer 402, and the overcoat layer 120 are selectively removed while preserving the pattern-reversing material 132, creating a structure where the pattern-reversing material 132 extends above the backside surface of the substrate 102 as discrete raised features. In some embodiments, the deprotected regions 414, the protective layer 402, and the overcoat layer 120 may be selectively removed as described above with reference to FIG. 4G, and the description is not repeated herein.

In FIG. 5C, a dielectric layer 134 is formed over the substrate 102 and surrounding the pattern-reversing material 132. In some embodiments, the dielectric layer 134 may be formed as described above with reference to FIG. 4H, and the description is not repeated herein.

In FIG. 5D, the pattern-reversing material 132 (see FIG. 5C) is selectively removed, creating recesses 502 in the dielectric layer 134 that extend down to the substrate 102 and expose the underlying TSVs 104. In some embodiments, the pattern-reversing material 132 (see FIG. 5C) may be selectively removed as described above with reference to FIG. 1M, and the description is not repeated herein.

In FIG. 5E, conductive features 418 are formed within the recesses 502 (see FIGS. 5D), establishing electrical connections between the TSVs 104 and a subsequently formed backside power distribution network. In some embodiments, the conductive features 418 may be formed in the recesses 502 (see FIGS. 5D) as described above with reference to FIG. 4F, and the description is not repeated herein. Subsequently, a backside power distribution network 144 is formed over the dielectric layer 134 and electrically connected to the conductive features 418 as described above with reference to FIG. 4H, and the description is not repeated herein.

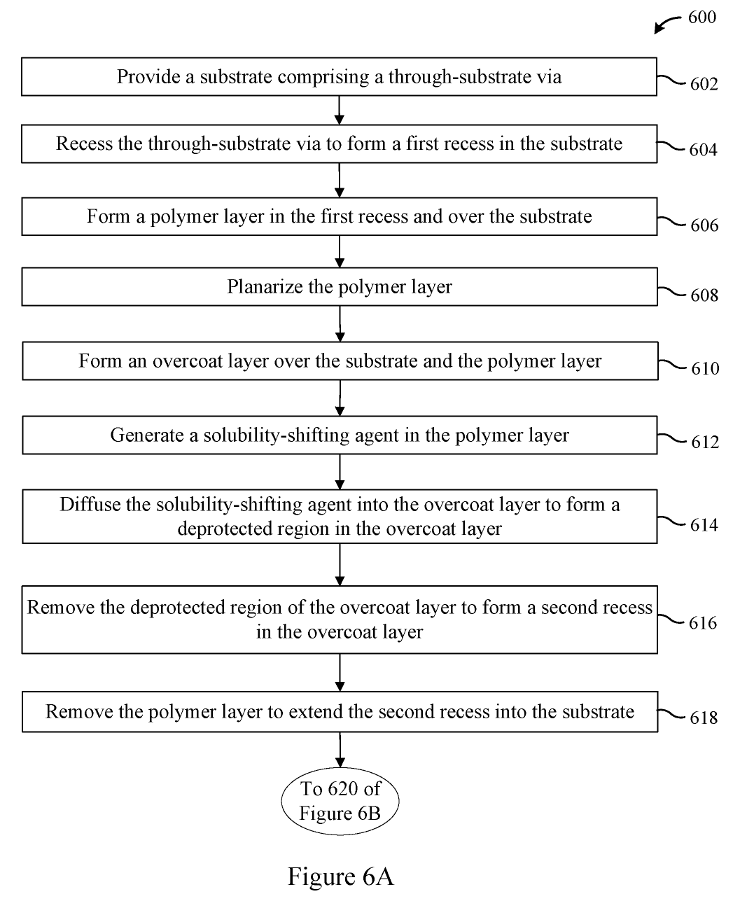

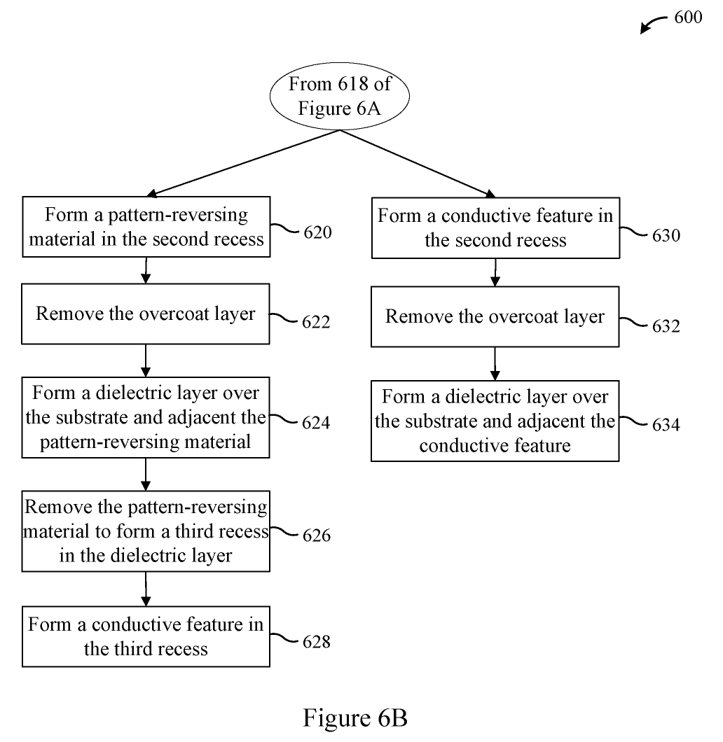

FIGS. 6A and 6B illustrate a flow diagram of a method 600 for forming self-aligned features, in accordance with various embodiments. Although shown in a particular sequence, it should be appreciated that the steps of the method 600 may be performed in any suitable sequence. Furthermore, one or more steps of the method 600 may be omitted.

The method 600 begins with step 602 when a substrate (e.g., substrate 102 of FIG. 1A) comprising a through-substrate via (e.g., TSV 104 of FIG. 1A) is provided, as described in FIG. 1A. In step 604, the through-substrate via is recessed to form a first recess (e.g., recess 114 of FIG. 1A) in the substrate, as described in FIG. 1B. In step 606, a polymer layer (e.g., polymer material 116 of FIG. 1C) is formed in the first recess and over the substrate, as described in FIG. 1C. In step 608, the polymer layer is planarized, as described in FIG. 1D.

In step 610, an overcoat layer (e.g., overcoat layer 120 of FIG. 1E) is formed over the substrate and the polymer layer, as described in FIG. 1E. In step 612, a solubility-shifting agent (e.g., solubility-shifting agent 124 of FIG. 1F) is generated in the polymer layer, as described in FIG. 1F. In step 614, the solubility-shifting agent is diffused into the overcoat layer to form a deprotected region (e.g., deprotected region 128 of FIG. 1H) in the overcoat layer, as described in FIGS. 1G and 1H. In step 616, the deprotected region of the overcoat layer is removed to form a second recess (e.g., recess 130 of FIG. 1I) in the overcoat layer, as described in FIG. 1I. In step 618, the polymer layer is removed to extend the second recess into the substrate, as described in FIG. 1I.

In one embodiment, the method 600 proceeds to step 620 after performing step 618. In step 620, a pattern-reversing material (e.g., pattern-reversing material 132 of FIG. 1J) is formed in the second recess, as described in FIG. 1J. In step 622, the overcoat layer is removed while preserving the pattern-reversing material, as described in FIG. 1K. In step 624, a dielectric layer (e.g., dielectric layer 134 of FIG. 1L) is formed over the substrate and adjacent the pattern-reversing material, as described in FIG. 1L. In step 626, the pattern-reversing material is removed to form a third recess (e.g., recess 136 of FIG. 1M) in the dielectric layer, as described in FIG. 1M. In step 628, a conductive feature (e.g., conductive feature 138 of FIG. 1N) is formed in the third recess, as described in FIG. 1N.

In another embodiment, the method 600 proceeds to step 630 after performing step 618. In step 630, a conductive feature (e.g., conductive feature 138 of FIG. 2A) is formed in the second recess, as described in FIG. 2A. In step 632, the overcoat layer is removed, as described in FIG. 2B. In step 634, a dielectric layer (e.g., dielectric layer 134 of FIG. 2C) is formed over the substrate and adjacent the conductive feature, as described in FIG. 2C.

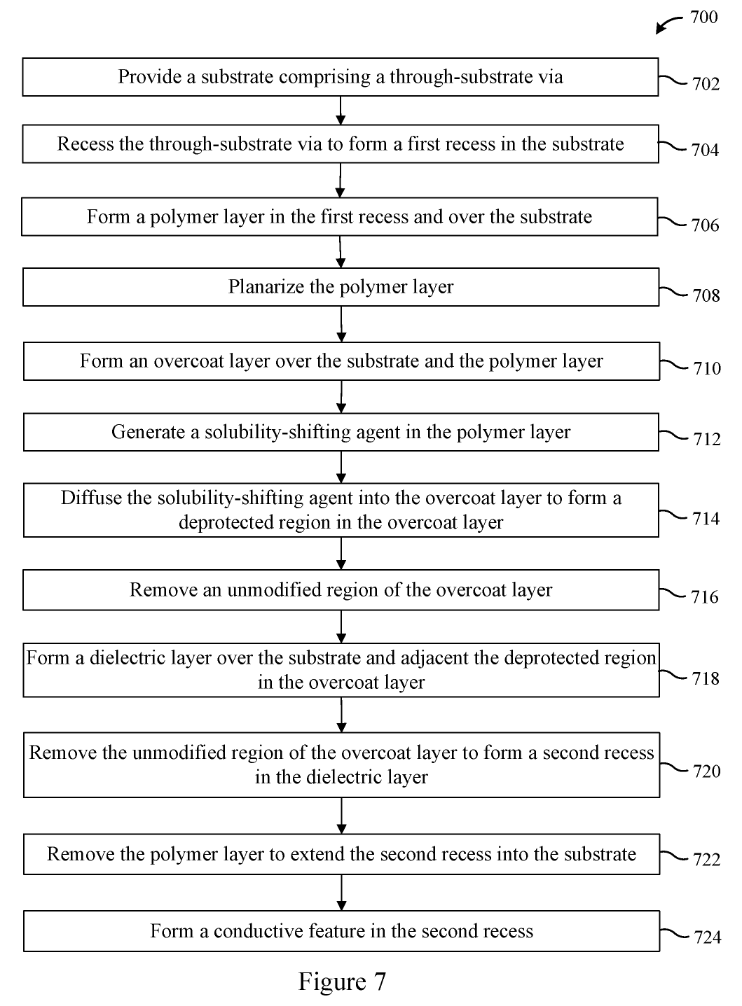

FIG. 7 illustrates a flow diagram of a method 700 for forming self-aligned features, in accordance with various embodiments. Although shown in a particular sequence, it should be appreciated that the steps of the method 700 may be performed in any suitable sequence. Furthermore, one or more steps of the method 700 may be omitted.

The method 700 begins with step 702 when a substrate (e.g., substrate 102 of FIG. 1A) comprising a through-substrate via (e.g., TSV 104 of FIG. 1A) is provided, as described in FIG. 1A. In step 704, the through-substrate via is recessed to form a first recess (e.g., recess 114 of FIG. 1A) in the substrate, as described in FIG. 1B. In step 706, a polymer layer (e.g., polymer material 116 of FIG. 1C) is formed in the first recess and over the substrate, as described in FIG. 1C. In step 708, the polymer layer is planarized, as described in FIG. 1D.

In step 710, an overcoat layer (e.g., overcoat layer 120 of FIG. 1E) is formed over the substrate and the polymer layer, as described in FIG. 1E. In step 712, a solubility-shifting agent (e.g., solubility-shifting agent 124 of FIG. 1F) is generated in the polymer layer, as described in FIG. 1F. In step 714, the solubility-shifting agent is diffused into the overcoat layer to form a deprotected region (e.g., deprotected region 128 of FIG. 1H) in the overcoat layer, as described in FIGS. 1G and 1H.

In step 716, an unmodified region of the overcoat layer is removed, as described in FIG. 3A. In step 718, a dielectric layer (e.g., dielectric layer 134 of FIG. 3B) is formed over the substrate and adjacent the deprotected region of the overcoat layer, as described in FIG. 3B. In step 720, the modified region of the overcoat layer is removed to form a second recess (e.g., recess 136 of FIG. 3B) in the dielectric layer, as described in FIG. 3C. In step 722, the polymer layer is removed to extend the second recess into the substrate, as described in FIG. 3C. In step 724, a conductive feature (e.g., conductive feature 138 of FIG. 3D) is formed in the second recess, as described in FIG. 3D.

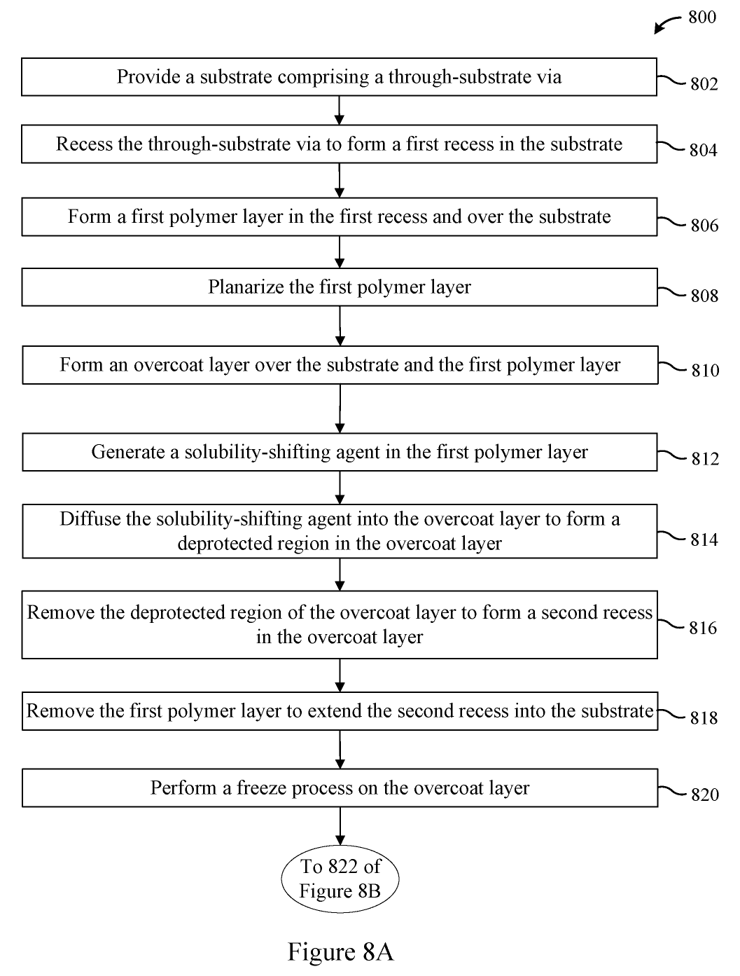

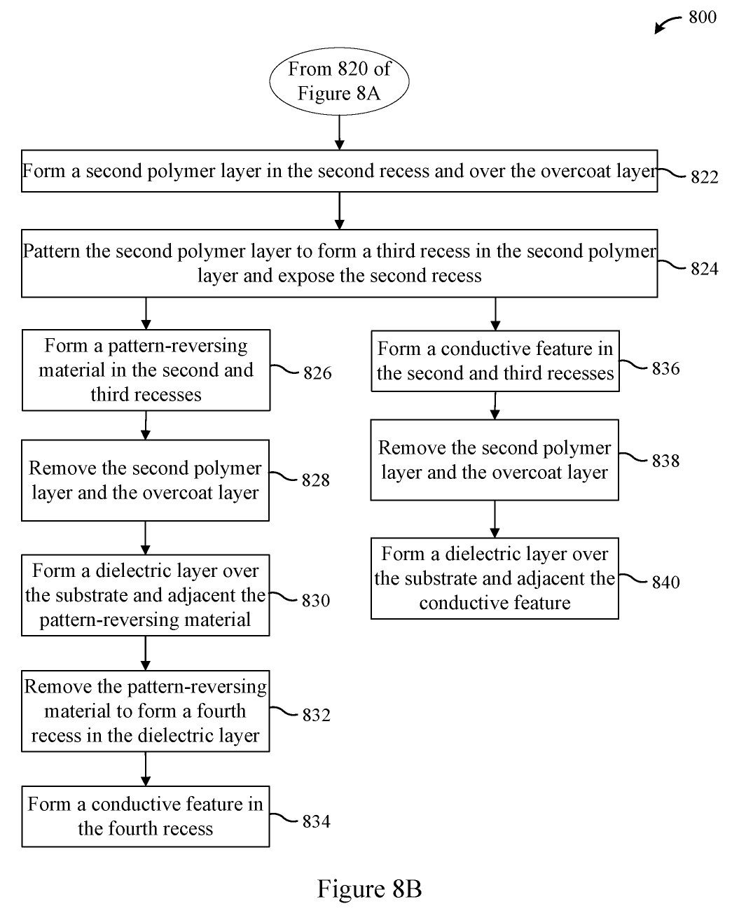

FIGS. 8A and 8B illustrate a flow diagram of a method 800 for forming self-aligned features, in accordance with various embodiments. Although shown in a particular sequence, it should be appreciated that the steps of the method 800 may be performed in any suitable sequence. Furthermore, one or more steps of the method 800 may be omitted.

The method 800 begins with step 802 when a substrate (e.g., substrate 102 of FIG. 1A) comprising a through-substrate via (e.g., TSV 104 of FIG. 1A) is provided, as described in FIG. 1A. In step 804, the through-substrate via is recessed to form a first recess (e.g., recess 114 of FIG. 1A) in the substrate, as described in FIG. 1B. In step 806, a first polymer layer (e.g., polymer material 116 of FIG. 1C) is formed in the first recess and over the substrate, as described in FIG. 1C. In step 808, the first polymer layer is planarized, as described in FIG. 1D.

In step 810, an overcoat layer (e.g., overcoat layer 120 of FIG. 1E) is formed over the substrate and the first polymer layer, as described in FIG. 1E. In step 812, a solubility-shifting agent (e.g., solubility-shifting agent 124 of FIG. 1F) is generated in the first polymer layer, as described in FIG. 1F. In step 814, the solubility-shifting agent is diffused into the overcoat layer to form a deprotected region (e.g., deprotected region 128 of FIG. 1H) in the overcoat layer, as described in FIGS. 1G and 1H. In step 816, the deprotected region of the overcoat layer is removed to form a second recess (e.g., recess 130 of FIG. 1I) in the overcoat layer, as described in FIG. 1I. In step 818, the first polymer layer is removed to extend the second recess into the substrate, as described in FIG. 1I.

In step 820, a freeze process is performed on the overcoat layer, as described in FIG. 4A. In step 822, a second polymer layer (e.g., polymer material 404 of FIG. 4B) is formed in the second recess and over the overcoat layer, as described in FIG. 4B. In step 824, the second polymer layer is patterned to form a third recess (e.g., recess 416 of FIG. 4E) in the second polymer layer and expose the second recess, as described in FIGS. 4C, 4D, and 4E, .

In one embodiment, the method 800 proceeds to step 826 after performing step 824. In step 826, a pattern-reversing material (e.g., pattern-reversing material 132 of FIG. 5A) is formed in the second and third recesses, as described in FIG. 5A. In step 828, the second polymer layer and the overcoat layer are removed while preserving the pattern-reversing material, as described in FIG. 5B. In step 830, a dielectric layer (e.g., dielectric layer 134 of FIG. 5C) is formed over the substrate and adjacent the pattern-reversing material, as described in FIG. 5C. In step 832, the pattern-reversing material is removed to form a fourth recess (e.g., recess 502 of FIG. 5D) in the dielectric layer, as described in FIG. 5D. In step 834, a conductive feature (e.g., conductive feature 418 of FIG. 5E) is formed in the fourth recess, as described in FIG. 5E.

In another embodiment, the method 800 proceeds to step 836 after performing step 824. In step 836, a conductive feature (e.g., conductive feature 418 of FIG. 4F) is formed in the second and third recesses, as described in FIG. 4F. In step 838, the second polymer layer and the overcoat layer are removed, as described in FIG. 4G. In step 840, a dielectric layer (e.g., dielectric layer 134 of FIG. 4H) is formed over the substrate and adjacent the conductive feature, as described in FIG. 4H.

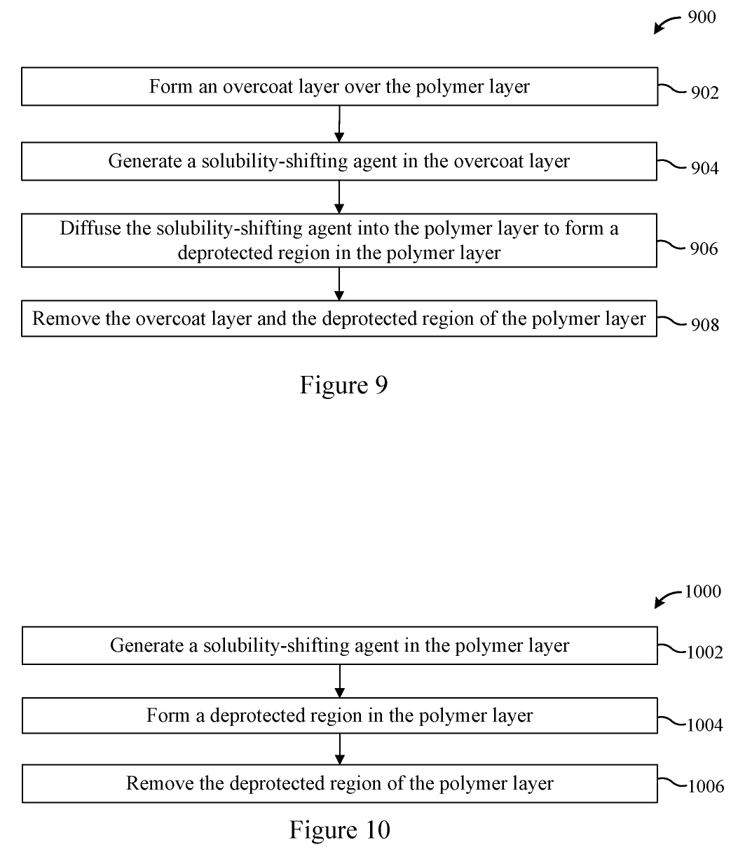

FIG. 9 illustrates a flow diagram of a method 900 for planarizing a polymer layer, in accordance with various embodiments. Although shown in a particular sequence, it should be appreciated that the steps of the method 900 may be performed in any suitable sequence. Furthermore, one or more steps of the method 900 may be omitted. The method 900 may be used to implement steps 608, 708, 808 of the methods 600, 700, and 800, respectively (see FIGS. 6A, 6B, 7, 8A and 8B, ).

The method 900 begins with step 902 when an overcoat layer (e.g., overcoat layer 146 of FIG. 1O) is formed over the polymer layer (e.g., polymer material 116 of FIG. 1O), as described in FIG. 1O. In step 904, a solubility-shifting agent (e.g., solubility-shifting agent 152 of FIG. 1P) is generated in the overcoat layer, as described in FIG. 1P.

In step 906, the solubility-shifting agent is diffused into the polymer layer to form a deprotected region (e.g., deprotected region 156 of FIG. 1Q) in the polymer layer, as described in FIG. 1Q. In step 908, the overcoat layer and the deprotected region of the polymer layer are removed, as described in FIG. 1Q.

FIG. 10 illustrates a flow diagram of a method 1000 for planarizing a polymer layer, in accordance with various embodiments. Although shown in a particular sequence, it should be appreciated that the steps of the method 1000 may be performed in any suitable sequence. Furthermore, one or more steps of the method 1000 may be omitted. The method 1000 may be used to implement steps 608, 708, 808 of the methods 600, 700, and 800, respectively (see FIGS. 6A, 6B, 7, 8A,8B, ).

The method 1000 begins with step 1002 when a solubility-shifting agent (e.g., solubility-shifting agent 160 of FIG. 1R) is generated in the polymer layer (e.g., polymer material 116 of FIG. 1O), as described in FIG. 1R. In step 1004, a deprotected region (e.g., deprotected region 164 of FIG. 1S) is formed in the polymer layer, as described in FIG. 1S. In step 1006, the deprotected region of the polymer layer is removed, as described in FIG. 1S.

Example embodiments of the disclosure are described below. Other embodiments can also be understood from the entirety of the specification as well as the claims filed herein.

Example 1. A method including: providing a substrate including a through-silicon via (TSV), where the TSV extends into the substrate from a first surface of the substrate; recessing the TSV to form a first recess in the substrate; filling the first recess with a first polymer material, the first polymer material including a first agent-generating ingredient, a first surface of the first polymer material being level with the first surface of the substrate; forming a first overcoat layer over the first surface of the first polymer material and the first surface of the substrate; generating a first solubility-shifting agent in the first polymer material from the first agent-generating ingredient; diffusing the first solubility-shifting agent into the first overcoat layer to form a first deprotected region in the first overcoat layer; and removing the first deprotected region of the first overcoat layer and the first polymer material to form a second recess.

Example 2. The method of Example 1, where filling the first recess with the first polymer material includes: depositing the first polymer material in the first recess and over the first surface of the substrate; depositing a second overcoat layer over the first polymer material, the first overcoat layer including a second agent-generating ingredient; generating a second solubility-shifting agent in the second overcoat layer from the second agent-generating ingredient; diffusing the second solubility-shifting agent into the first polymer material to form a second deprotected region in the first polymer material, where a bottom surface of the second deprotected region is level with the first surface of the substrate; and removing the second overcoat layer and the second deprotected region of the first polymer material.

Example 3. The method of Example 1, where filling the first recess with the first polymer material includes: depositing the first polymer material in the first recess and over the first surface of the substrate; generating the first solubility-shifting agent in the first polymer material from the first agent-generating ingredient, where the first solubility-shifting agent is generated in the first polymer material above the first surface of the substrate; reacting the first solubility-shifting agent with the first polymer material to form a second deprotected region in the first polymer material, where a bottom surface of the second deprotected region is level with the first surface of the substrate; and removing the second deprotected region of the first polymer material.

Example 4. The method of any of Examples 1 to 3, further including: performing a freeze process on the first overcoat layer; depositing a second polymer material in the second recess and over the first overcoat layer, the second polymer material including a second agent-generating ingredient; and patterning the second polymer material to form a third recess in the second polymer material and expose the second recess.

Example 5. The method of Examples 4, where patterning the second polymer material includes: exposing the second polymer material to an electromagnetic radiation to generate a second solubility-shifting agent in the second polymer material from the second agent-generating ingredient; reacting the second solubility-shifting agent with the second polymer material to form second deprotected regions in the second polymer material; and removing unmodified regions of the second polymer material.

Example 6. The method of any of Examples 4 and 5, where performing the freeze process on the first overcoat layer includes forming a protective layer on exposed surfaces of the first overcoat layer.

Example 7. The method of any of Examples 4 to 6, further including: forming a conductive feature in the second recess and the third recess; and removing the second polymer material and the first overcoat layer; and embedding the conductive feature in a dielectric layer.

Example 8. The method of Example 7, where the conductive feature is a part of a backside power distribution network.

Example 9. The method of any of Examples 4 to 8, further including: depositing a pattern-reversing material in the second and third recesses; removing the second polymer material and the first overcoat layer; forming a dielectric layer over the first surface of the substrate and adjacent the pattern-reversing material; removing the pattern-reversing material to form a fourth recess in the dielectric layer; and forming a conductive feature in the fourth recess.

Example 10. The method of any of Examples 1 to 9, where: generating the first solubility-shifting agent in the first polymer material includes exposing the first polymer material to an electromagnetic radiation; and diffusing the first solubility-shifting agent into the first overcoat layer includes performing a thermal process.

Example 11. The method of any of Examples 1 to 10, where removing the first deprotected region of the first overcoat layer and the first polymer material includes dissolving the first deprotected region of the first overcoat layer and the first polymer material in a same solvent.

Example 12. The method of any of Examples 1 to 11, wherein generating the first solubility-shifting agent in the first polymer material includes performing a thermal process.

Example 13. A method including: providing a substrate including a through-silicon via (TSV), where the TSV extends into the substrate from a first surface of the substrate; etching back the TSV to form a first recess in the substrate; depositing a first polymer material in the first recess, the first polymer material including a first agent-generating ingredient; forming an overcoat layer over the first polymer material and the substrate; generating a first solubility-shifting agent in the first polymer material from the first agent-generating ingredient; diffusing the first solubility-shifting agent into the overcoat layer to form a deprotected region in the overcoat layer; removing the deprotected region of the overcoat layer to form a second recess in the overcoat layer; removing the first polymer material to extend the second recess into the substrate; performing a freeze process on the overcoat layer to form a protective layer on exposed surfaces of the overcoat layer; overfilling the second recess with a second polymer material, the second polymer material including a second agent-generating ingredient; and patterning the second polymer material to form a third recess in the second polymer material and expose the second recess.

Example 14. The method of Example 13, further including: forming a conductive feature in the second and third recesses; and removing the second polymer material and the overcoat layer.

Example 15. The method of Example 14, where the conductive feature is a part of a backside power distribution network.

Example 16. The method of any of Examples 13 to 15, further including: depositing a pattern-reversing material in the second and third recesses; removing the second polymer material and the overcoat layer; forming a dielectric layer over the first surface of the substrate and adjacent the pattern-reversing material; removing the pattern-reversing material to form a fourth recess in the dielectric layer; and forming a conductive feature in the fourth recess.

Example 17. The method of any of Examples 13 to 16, where: generating the first solubility-shifting agent in the first polymer material includes exposing the first polymer material to an electromagnetic radiation; and diffusing the first solubility-shifting agent into the overcoat layer includes performing a thermal process.

Example 18. The method of any of Examples 13 to 17, where generating the first solubility-shifting agent in the first polymer material includes performing a thermal process.

Example 19. The method of any of Examples 13 to 18, where patterning the second polymer material includes: exposing the second polymer material to an electromagnetic radiation to generate a second solubility-shifting agent in the second polymer material from the second agent-generating ingredient; reacting the second solubility-shifting agent with the second polymer material to form second deprotected regions in the second polymer material; and dissolving unmodified regions of the second polymer material in a solvent.

Example 20. A method including: providing a substrate including a through-silicon via (TSV), where the TSV extends into the substrate from a first surface of the substrate; etching the TSV to form a first recess in the substrate; filling the first recess with a first photoresist, a first surface of the first photoresist being level with the first surface of the substrate; forming an overcoat layer over the first surface of the first photoresist and the first surface of the substrate; generating a first solubility-shifting agent in the first photoresist; diffusing the first solubility-shifting agent into the overcoat layer to form a deprotected region in the overcoat layer; dissolving the deprotected region of the overcoat layer and the first photoresist to form a second recess; performing a freeze process on the overcoat layer; depositing a second photoresist in the second recess and over the overcoat layer; and patterning the second photoresist to form a third recess in the second photoresist and expose the second recess.

Example 21. The method of Example 20, further including: forming a conductive feature in the second and third recesses; dissolving the second photoresist and the overcoat layer in a solvent; and depositing a dielectric layer over the substrate and surrounding the conductive feature.

Example 22. The method of any of Examples 20 and 21, where the third recess is wider than the second recess.

Example 23. The method of any of Examples 20 to 22, where patterning the second photoresist includes: exposing the second photoresist to an electromagnetic radiation through a reticle to generate a second solubility-shifting agent in the second photoresist; performing a thermal process to react the second solubility-shifting agent with the second photoresist and form second deprotected regions in the second photoresist; and dissolving unmodified regions of the second photoresist in a solvent.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
providing a substrate comprising a through-silicon via (TSV), wherein the TSV extends into the substrate from a first surface of the substrate;
recessing the TSV to form a first recess in the substrate;
filling the first recess with a first polymer material, the first polymer material comprising a first agent-generating ingredient, a first surface of the first polymer material being level with the first surface of the substrate;
forming a first overcoat layer over the first surface of the first polymer material and the first surface of the substrate;
generating a first solubility-shifting agent in the first polymer material from the first agent-generating ingredient;
diffusing the first solubility-shifting agent into the first overcoat layer to form a first deprotected region in the first overcoat layer; and
removing the first deprotected region of the first overcoat layer and the first polymer material to form a second recess.

2. The method of claim 1, wherein filling the first recess with the first polymer material comprises:
depositing the first polymer material in the first recess and over the first surface of the substrate;
depositing a second overcoat layer over the first polymer material, the first overcoat layer comprising a second agent-generating ingredient;
generating a second solubility-shifting agent in the second overcoat layer from the second agent-generating ingredient;
diffusing the second solubility-shifting agent into the first polymer material to form a second deprotected region in the first polymer material, wherein a bottom surface of the second deprotected region is level with the first surface of the substrate; and
removing the second overcoat layer and the second deprotected region of the first polymer material.

3. The method of claim 1, wherein filling the first recess with the first polymer material comprises:
depositing the first polymer material in the first recess and over the first surface of the substrate;
generating the first solubility-shifting agent in the first polymer material from the first agent-generating ingredient, wherein the first solubility-shifting agent is generated in the first polymer material above the first surface of the substrate;
reacting the first solubility-shifting agent with the first polymer material to form a second deprotected region in the first polymer material, wherein a bottom surface of the second deprotected region is level with the first surface of the substrate; and
removing the second deprotected region of the first polymer material.

4. The method of claim 1, further comprising:
performing a freeze process on the first overcoat layer;
depositing a second polymer material in the second recess and over the first overcoat layer, the second polymer material comprising a second agent-generating ingredient; and
patterning the second polymer material to form a third recess in the second polymer material and expose the second recess.

5. The method of claim 4, wherein patterning the second polymer material comprises:
exposing the second polymer material to an electromagnetic radiation to generate a second solubility-shifting agent in the second polymer material from the second agent-generating ingredient;
reacting the second solubility-shifting agent with the second polymer material to form second deprotected regions in the second polymer material; and
removing unmodified regions of the second polymer material.

6. The method of claim 4, wherein performing the freeze process on the first overcoat layer comprises forming a protective layer on exposed surfaces of the first overcoat layer.

7. The method of claim 4, further comprising:
forming a conductive feature in the second recess and the third recess; and
removing the second polymer material and the first overcoat layer; and
embedding the conductive feature in a dielectric layer.

8. The method of claim 7, wherein the conductive feature is a part of a backside power distribution network.

9. The method of claim 4, further comprising:
depositing a pattern-reversing material in the second and third recesses;
removing the second polymer material and the first overcoat layer;
forming a dielectric layer over the first surface of the substrate and adjacent the pattern-reversing material;
removing the pattern-reversing material to form a fourth recess in the dielectric layer; and
forming a conductive feature in the fourth recess.

10. A method comprising:
providing a substrate comprising a through-silicon via (TSV), wherein the TSV extends into the substrate from a first surface of the substrate;
etching back the TSV to form a first recess in the substrate;
depositing a first polymer material in the first recess, the first polymer material comprising a first agent-generating ingredient;
forming an overcoat layer over the first polymer material and the substrate;
generating a first solubility-shifting agent in the first polymer material from the first agent-generating ingredient;
diffusing the first solubility-shifting agent into the overcoat layer to form a deprotected region in the overcoat layer;
removing the deprotected region of the overcoat layer to form a second recess in the overcoat layer;
removing the first polymer material to extend the second recess into the substrate;
performing a freeze process on the overcoat layer to form a protective layer on exposed surfaces of the overcoat layer;
overfilling the second recess with a second polymer material, the second polymer material comprising a second agent-generating ingredient; and
patterning the second polymer material to form a third recess in the second polymer material and expose the second recess.

11. The method of claim 10, further comprising:
forming a conductive feature in the second and third recesses; and
removing the second polymer material and the overcoat layer.

12. The method of claim 11, wherein the conductive feature is a part of a backside power distribution network.

13. The method of claim 10, further comprising:
depositing a pattern-reversing material in the second and third recesses;
removing the second polymer material and the overcoat layer;
forming a dielectric layer over the first surface of the substrate and adjacent the pattern-reversing material;
removing the pattern-reversing material to form a fourth recess in the dielectric layer; and
forming a conductive feature in the fourth recess.

14. The method of claim 10, wherein:
generating the first solubility-shifting agent in the first polymer material comprises exposing the first polymer material to an electromagnetic radiation; and
diffusing the first solubility-shifting agent into the overcoat layer comprises performing a thermal process.

15. The method of claim 10, wherein generating the first solubility-shifting agent in the first polymer material comprises performing a thermal process.

16. The method of claim 10, wherein patterning the second polymer material comprises:
exposing the second polymer material to an electromagnetic radiation to generate a second solubility-shifting agent in the second polymer material from the second agent-generating ingredient;
reacting the second solubility-shifting agent with the second polymer material to form second deprotected regions in the second polymer material; and
dissolving unmodified regions of the second polymer material in a solvent.

17. A method comprising:
providing a substrate comprising a through-silicon via (TSV), wherein the TSV extends into the substrate from a first surface of the substrate;
etching the TSV to form a first recess in the substrate;
filling the first recess with a first photoresist, a first surface of the first photoresist being level with the first surface of the substrate;
forming an overcoat layer over the first surface of the first photoresist and the first surface of the substrate;
generating a first solubility-shifting agent in the first photoresist;
diffusing the first solubility-shifting agent into the overcoat layer to form a deprotected region in the overcoat layer;
dissolving the deprotected region of the overcoat layer and the first photoresist to form a second recess;
performing a freeze process on the overcoat layer;
depositing a second photoresist in the second recess and over the overcoat layer; and
patterning the second photoresist to form a third recess in the second photoresist and expose the second recess.

18. The method of claim 17, further comprising:
forming a conductive feature in the second and third recesses;
dissolving the second photoresist and the overcoat layer in a solvent; and
depositing a dielectric layer over the substrate and surrounding the conductive feature.

19. The method of claim 17, wherein the third recess is wider than the second recess.

20. The method of claim 17, wherein patterning the second photoresist comprises:
exposing the second photoresist to an electromagnetic radiation through a reticle to generate a second solubility-shifting agent in the second photoresist;
performing a thermal process to react the second solubility-shifting agent with the second photoresist and form second deprotected regions in the second photoresist; and
dissolving unmodified regions of the second photoresist in a solvent.
